(19) United States
(12) Patent Application Publication
(10) Pub. No.: US 2021/0150403 A1
(43) Pub. Date: May 20, 2021

(54) Methods and Circuits for Copying Qubits and Quantum Representation of Images and Signals

(71) Applicant: Board of Regents, The University of Texas System, Austin, TX (US)

(72) Inventors: Artyom GRIGORYAN, San Antonio, TX (US); Sos M. AGAIAN, Staten Island, NY (US)

(21) Appl. No.: 17/099,310

(22) Filed: Nov. 16, 2020

Related U.S. Application Data
(60) Provisional application No. 62/936,062, filed on Nov. 15, 2019.
(60) Provisional application No. 62/951,178, filed on Dec. 20, 2019.

(51) Int. Cl. G06N 10/00; G06F 17/18; H03K 19/195

(52) U.S. Cl. CPC G06N 10/00; H03K 19/195; G06F 17/18

(57) ABSTRACT

Embodiments may provide techniques by which qubits may be copied and observed in a quantum computing system, as well as for techniques by which images may be represented in quantum computing systems. In an embodiment, a method for copying a qubit may comprise receiving a qubit in a genetic state of linear superposition |ψ [symbol] =a| [symbol] +b|1 [symbol] , applying sequentially a plurality of CNOT operators to form a result that may comprise a 4-qubit output state having duplicated qubits in a plurality of qubits of the output state, measuring the 4-qubit output state, applying a 2-Controlled-NOT operator with a target qubit to the output of the second CNOT operator to output a plurality of qubits, and measuring a qubit of the output plurality of qubits to obtain duplicated qubits |ψ² [symbol] .

### CROSS-REFERENCE TO RELATED APPLICATIONS

This application claims the benefit of U.S. Provisional Application No. 62/936,062, filed Nov. 15, 2019, and U.S. Provisional Application No. 62/951,178, filed Dec. 20, 2019, the contents of all of which are incorporated herein in their entirety.

### BACKGROUND

The present invention relates generally to quantum computing systems and information systems, and more particularly, relates to quantum computing, qubit duplication, teleportation protocol, quantum image/signal representation, quantum signal processing, and to quaternion quantum image processing.

Among the important problems in using quantum computing to process data are: How to copy qubits, and how to represent data (signal, image, and video data) using quantum states without losing information. Currently, it is not possible to copy the qubit. In quantum computing, for instance, the CNOT operation does not allow for copying the qubits, as does traditional computing, when copying the bits. This statement is captured by the well-known no-cloning theorem; qubit information cannot be copied. That is, arbitrary unknown qubit states cannot be copied perfectly. In a digital computer, when copying a bit, a new cell is allocated in the computer's memory, the value of the bit is read, and then this value is written to the cell. Such a read-write-out procedure is likely to be possible in quantum systems. For each state of a qubit, probably somewhere in space, an identical state is reproduced. It may seem a little strange that with an infinite number of possible states for qubits, for example, in two separate atoms, no one will ever be able to observe whether two electrons can communicate with each other and remain in an equal state.

Many quantum image-processing algorithms are based on the classical theory and methods of image processing that are well developed today. Therefore, much attention is paid to the issue of representing images in quantum calculations. This is exactly the bridge that needs to be transferred from classical theory to quantum theory of image processing. Such representations should be developed, analyzed, and united in order to select a unified format in the future or several such ones in quantum imaging, such as, for example, the well-known classical computing formats in the RGB, CMY(K), XYZ color models. Such unified formats will facilitate research work in the field of quantum visualization. Further, as algorithms specific to quantum computing are developed in the future, this will open a new page in image processing. Thus, the image representation in quantum space is a first step in processing images in quantum algorithms. Different approaches have proposed for quantum image representation, such as the qubit lattice model (QLM), the real ket model (RKM), the flexible representation for quantum images (FRQI), the novel enhanced quantum representation (NEQR), the generalized quantum image representation (GQIR), and the arbitrary superposition state (NASS) and its version with three components (NASSTC).

Recently it has been shown that quaternion algebra may be a very powerful tool in color image processing. Different methods of representation and processing have been developed for processing color images in quaternion algebra. Examples may include the application of the alpha-rooting method with the quaternion two-dimensional discrete Fourier transform, as well as the quaternion histogram equalization in color image enhancement. While the traditional methods of color image processing are reduced to each color-channel separately, for instance, in the RGB model, these color components may be processed simultaneously when using the quaternion-based representation. Further, much attention has been given to future quantum computers to develop effective solutions to many difficult tasks in computer and electrical engineering, including color image processing. Different models of representation for grayscale and color images have been proposed in quantum computing, which can be divided into two classes. In models of one class, the concept of a quantum pixel is applied, and in the models of the second class, the information of the image is encoded in amplitudes of states of qubits presenting the grayscale or color image; these amplitudes are real and complex amplitudes.

Accordingly, a need arises for techniques by which qubits may be copied and observed in a quantum computing system, as well as for techniques by which images may be represented in quantum computing systems.

### SUMMARY

Embodiments may provide techniques by which qubits may be copied and observed in a quantum computing system, as well as for techniques by which images may be represented in quantum computing systems. Embodiments may include techniques for copying qubit system followed by separation of the qubits so that they may be observed. In embodiments, a quantum copying/cloning qubits system may include, for example, two quantum circuits with two CNOT operations each, which generate the duplicated qubits in two qubits of the calculated 4-qubit state. Embodiments may include techniques for generating a discrete data (signals and images) multi-qubit representation of the signal representation system. Embodiments may include techniques for generating color quantum models. Embodiments may include techniques for providing a quaternion quantum image processing system.

Embodiments may utilize two quantum circuits with two CNOT operations each and may show the duplicated qubits in two qubits and may calculate using a 4-qubit state. In other words, it may show that there exist quantum schemes that allow measuring duplicated qubits.

Embodiments may include systems and methods for representing discrete signals and images in a quantum computing system, by mapping the input data into the unit circle, describing discrete signals by using the Fourier transform qubit representation (FTQR). For grayscale images, we consider the similar concept of the Fourier transform representation of images, and describing color (for example, using RGB model) images, by using the innovated 3-point discrete Fourier transform (DFT) of color qubits.

Embodiments may include systems and methods for processing color images as a quaternion data representation, which includes color images together with their grayscale components, systems and methods for presenting the quaternion number in two-qubit and using image representation in each quantum pixel, and systems and methods for quaternion image representation by (r+s+2) qubits, when N=2^{r} and M=2^{s}, r,s>1. Moreover, the number of qubits for representing the grayscale image may be reduced to (r+s), when using the quaternion 2-qubit concept. System and methods for representation image the minimum number of qubits.

Embodiments may include a framework of quaternion-based representation that may be used in many imaging applications including image enhancement, filtrating, and restoration, that may be applied to generations of octonion-based images quantum circuits, which will allow for effective processing simultaneously two-color images or up to eight grayscale images, and that may be used for color images other than RGB color models, such as the CMY(K), XYZ, and YCbCr models.

In an embodiment, a method for copying a qubit may comprise receiving a qubit in a genetic state of linear superposition |ψ [symbol] =a|0 [symbol] +b|1), applying sequentially a plurality of CNOT operators to form a result that may comprise a 4-qubit output state having duplicated qubits in a plurality of qubits of the output state, measuring the 4-qubit output state, applying a 2-Controlled-NOT operator with a target qubit to the output of the second CNOT operator to output a plurality of qubits, and measuring a qubit of the output plurality of qubits to obtain duplicated qubits |ψ² [symbol] .

In embodiments, applying sequentially a plurality of CNOT operators may comprise applying a first CNOT operator (gate X) with a control qubit |ψ [symbol] and controlling (target) state |0 [symbol] to form a result that may comprise a 2-qubit state |φ [symbol] =a|00 [symbol] +b|1 [symbol] , applying a second CNOT operator with the control qubit |ψ [symbol] and a second input being |φ [symbol] ; wherein the target is a second qubit of |φ [symbol] , to form a result that may comprise a 4-qubit output state having duplicated qubits in the 2^{nd} and 3^{rd} qubits of the output state. Applying a 2-Controlled-NOT operator may comprise applying a 2-Controlled-NOT operator with a target qubit number of 3 to the output of the second CNOT operator to output a plurality of qubits Measuring a qubit of the output plurality of qubits may comprise measuring a last qubit of the output plurality of qubits to obtain duplicated qubits |ψ² [symbol] . Applying sequentially a plurality of CNOT operators may comprise applying a first CNOT operator (gate X) with a control qubit |ψ [symbol] and controlling (target) state |0 [symbol] to form a result that may comprise a 2-qubit state |φ [symbol] =a|00 [symbol] +b|11 [symbol] , applying a second CNOT operator with the control qubit |ψ [symbol] and a second input being |ψ [symbol] ; wherein the target is a first qubit of |φ [symbol] , to form a result that may comprise a 4-qubit output state having duplicated qubits in the 2^{nd} and 4^{th} qubits of the output state.

In embodiments, the method of claim 4, may further comprise applying a permutation of a 3-qubit state, to swap a first qubit and a second qubit of the second CNOT operator. Applying a 2-Controlled-NOT operator may comprise applying a 2-Controlled-NOT operator with a target qubit number of 3 to the output of the second CNOT operator to output a plurality of qubits Measuring a qubit of the output plurality of qubits may comprise measuring a last qubit of the output plurality of qubits to obtain duplicated qubits |ψ² [symbol] .

In an embodiment, a system for copying a qubit may comprise

a plurality of CNOT operator circuits sequentially connected and configured to receive a qubit in a genetic state of linear superposition |ψ [symbol] =a|0 [symbol] +b|1 [symbol] and to form therefrom a result that may comprise a 4-qubit output state having duplicated qubits in a plurality of qubits of the output state, circuitry configured to measure the 4-qubit output state, a 2-Controlled-NOT operator circuit configured with a target qubit input connected to the output of the second CNOT operator to output a plurality of qubits, and circuitry configured to measure a qubit of the output plurality of qubits to obtain duplicated qubits |ψ² [symbol] .

In embodiments, the plurality of CNOT operator circuits may comprise a first CNOT operator circuit (gate X) that may comprise a control qubit |ψ [symbol] input and a controlling (target) state |0 [symbol] input, and an output outputting a result that may comprise a 2-qubit state |φ [symbol] =a|00 [symbol] +b|11 [symbol] , a second CNOT operator circuit that may comprise a control qubit lip), a second input of |φ [symbol] , and a target input of a second qubit of |φ [symbol] , and an output outputting a result that may comprise a 4-qubit output state having duplicated qubits in the 2^{nd} and 3^{rd} qubits of the output state. The 2-Controlled-NOT operator circuit may be configured to apply a 2-Controlled-NOT operator with a target qubit number of 3 to the output of the second CNOT operator to output a plurality of qubits. The circuitry configured to measure a qubit of the output plurality of qubits may be further configured to measure a last qubit of the output plurality of qubits to obtain duplicated qubits |ψ² [symbol] . The plurality of CNOT operator circuits may comprise a first CNOT operator circuit (gate X) that may comprise a control qubit |ψ [symbol] input and a controlling (target) state |0 [symbol] input, and an output outputting a result that may comprise a 2-qubit state |φ [symbol] =a|00 [symbol] +b|11 [symbol] , a second CNOT operator circuit that may comprise a control qubit |ψ [symbol] , a second input of |φ [symbol] , and a target input of a first qubit of |φ [symbol] , and an output outputting a result that may comprise a 4-qubit output state having duplicated qubits in the 2^{nd} and 4^{th} qubits of the output state.

In embodiments, the system may further comprise permutation circuitry configured to apply a permutation of a 3-qubit state, to swap a first qubit and a second qubit of the second CNOT operator. The 2-Controlled-NOT operator circuit may be configured to apply a 2-Controlled-NOT operator with a target qubit number of 3 to the output of the second CNOT operator to output a plurality of qubits. The circuitry configured to measure a qubit of the output plurality of qubits may be further configured to measure a last qubit of the output plurality of qubits to obtain duplicated qubits |ψ² [symbol] .

In an embodiment, a method for the quantum representation of one-dimensional (1-D) signals may comprise receiving a discrete signal that may comprise information of length 2^{r}, r>1, mapping the discrete signal information into a first quarter circle, applying mapping coefficients to phases of basic states of qubits, and generating a quantum superposition state of the signal.

In an embodiment, a method for the quantum representation of grayscale images that may comprise receiving a discrete image that may comprise information of size 2^{r}×2^{s} pixels; r,s>1, mapping the discrete image information into a first quarter circle, applying mapping coefficients to phases of basic states of qubits, generating a quantum superposition state of the image, and generating a quantum representation of the image having (r+s) qubits.

In an embodiment, a method for the quantum representation of RGB color images by separate color components may comprise receiving a red component of an image that may comprise information of size 2^{r}×2^{s} pixels; r,s>1, mapping the red component image information into a first quarter circle, applying mapping coefficients to phases of basic states of qubits, generating an in phase quantum representation of the red component of the image, receiving a green component of the image that may comprise information of size 2^{r}×2^{s} pixels, mapping the green component image information into the first quarter circle, applying the mapping coefficients to the phases of basic states of qubits, generating an in phase quantum representation of the green component of the image, receiving a blue component of the image that may comprise information of size 2^{r}×2^{s} pixels, mapping the blue component image information into the first quarter circle, applying the mapping coefficients to the phases of basic states of qubits, generating an in phase quantum representation of the blue component of the image, and outputting the quantum representation of the color components of the image with (r+s) qubits each.

In an embodiment, a method for the quantum representation of RGB color images may comprise receiving a discrete color image that may comprise a red component, a green component, and a blue component, and each component that may comprise information of size 2^{r}×2^{s} pixels, r,s>1, dividing a unit circle into three parts, each of 120°, one part for each of the red, green, and blue components, mapping the red image information into a first part of the circle, applying mapping coefficients to phases of basic states of qubits for the first part of the circle, generating a Fourier transform quantum representation (FTQR) for the red component, mapping the green image information into a second part of the circle, applying the mapping coefficients to the phases of basic states of qubits for the second part of the circle, generating an FTQR for the green component, mapping the blue image information into a third part of the circle, applying the mapping coefficients to the phases of basic states of qubits for the third part of the circle. generating an FTQR for the blue component, uniting the three FTQRs in one quantum superposition with (r+s) qubits, and applying a 3-point discrete Fourier transform to qubits in color.

In an embodiment, a system for the quantum representation of RGB color images may comprise circuitry configured to receive a discrete color image comprising a red component, a green component, and a blue component, and each component comprising information of size 2^{r}×2^{s} pixels, r,s>1, circuitry configured to divide a unit circle into three parts, each of 120°, one part for each of the red, green, and blue components, circuitry configured to map the red image information into a first part of the circle, circuitry configured to apply mapping coefficients to phases of basic states of qubits for the first part of the circle, circuitry configured to generate a Fourier transform quantum representation (FTQR) for the red component, circuitry configured to map the green image information into a second part of the circle, circuitry configured to apply the mapping coefficients to the phases of basic states of qubits for the second part of the circle, circuitry configured to generate an FTQR for the green component, circuitry configured to map the blue image information into a third part of the circle, circuitry configured to apply the mapping coefficients to the phases of basic states of qubits for the third part of the circle, circuitry configured to generate an FTQR for the blue component, circuitry configured to unite the three FTQRs in one quantum superposition with (r+s) qubits, and circuitry configured to apply a 3-point discrete Fourier transform to qubits in color.

In an embodiment, a method for the quantum representation of RGB color images may comprise receiving a discrete color image that may comprise grayscale images of a red color component, a green color component, and a blue color component of the discrete color image, normalizing intensities of the grayscale images, generating a 3-point DFT of the normalized color components at each quantum pixel, and generating a quantum superposition wherein amplitudes represent the 3-point DFT of the color-qubit.

In embodiments, the method may further comprise applying color energy equalization to the intensity normalized grayscale images prior to generating the 3-D DFT. Generating the quantum superposition may comprise generating a quantum superposition wherein amplitudes represent the normalized intensities of the grayscale images.

In an embodiment, a system for the quantum representation of RGB color images may comprise circuitry configured to receive a discrete color image that may comprise grayscale images of a red color component, a green color component, and a blue color component of the discrete color image, circuitry configured to normalize intensities of the grayscale images, circuitry configured to generate a 3-point DFT of the normalized color components at each quantum pixel, circuitry configured to generate a quantum superposition wherein amplitudes represent the 3-point DFT of the color-qubit.

In embodiments, the system may further comprise circuitry configured to apply color energy equalization to the intensity normalized grayscale images prior to generating the 3-D DFT. The circuitry configured to generate the quantum superposition may be further configured to generate a quantum superposition wherein amplitudes represent the normalized intensities of the grayscale images.

In an embodiment, a method for quaternion quantum representation of color images may comprise receiving a discrete color image of size 2^{r}×2^{s} pixels, r,s>1, and that may comprise grayscale images of a red color component, a green color component, and a blue color component of the discrete color image, calculating a grayscale image that represents a brightness or intensity of the color image, normalizing intensity of grayscale images of the color components and the grayscale image of the color image, generating a plurality of quaternions from the grayscale images of the color components and the grayscale image of the color image, generating a quaternion 2-qubit state at a quantum pixel, generating a quantum superposition of the quaternion 2-qubit states to form a quantum representation of the color image, and outputting the quantum representation of the color image with (r+s+2) qubits.

In an embodiment, a system for quaternion quantum representation of color images may comprise circuitry configured to receive a discrete color image of size 2^{r}×2^{s} pixels, r,s>1, and that may comprise grayscale images of a red color component, a green color component, and a blue color component of the discrete color image, circuitry configured to calculate a grayscale image that represents a brightness or intensity of the color image, circuitry configured to normalize intensity of grayscale images of the color components and the grayscale image of the color image, circuitry configured to generate a plurality of quaternions from the grayscale images of the color components and the grayscale image of the color image, circuitry configured to generate a quaternion 2-qubit state at a quantum pixel, circuitry configured to generate a quantum superposition of the quaternion 2-qubit states to form a quantum representation of the color image, and circuitry configured to output the quantum representation of the color image with (r+s+2) qubits.

In an embodiment, a method for quaternion quantum representation of color images that may comprise receiving a discrete color image of size 2^{r}×2^{s} pixels, r,s>1, and that may comprise grayscale images of a red color component, a green color component, and a blue color component of the discrete color image, calculating a grayscale image that represents a brightness or intensity of the color image, normalizing intensity of grayscale images of the color components and the grayscale image of the color image, generating a plurality of quaternions from the grayscale images of the color components and the grayscale image of the color image, generating a representation of each of the plurality of quaternions in polar form, generating a single-qubit quaternion state at a quantum pixel, using a normalized imaginary part of the quaternion and an angular form of the grayscale image of the color image. generating a quantum superposition of the quaternion 2-qubit states to form a quantum representation of the color image, and reconstructing the color image from a measurement of the quantum superposition state of a quantum representation of the color image with (r+s+1) qubits.

In an embodiment, a system for quaternion quantum representation of color images may comprise circuitry configured to receive a discrete color image of size 2^{r}×2^{s} pixels, r,s>1, and that may comprise grayscale images of a red color component, a green color component, and a blue color component of the discrete color image, circuitry configured to calculate a grayscale image that represents a brightness or intensity of the color image, circuitry configured to normalize intensity of grayscale images of the color components and the grayscale image of the color image, circuitry configured to generate a plurality of quaternions from the grayscale images of the color components and the grayscale image of the color image, circuitry configured to generate a representation of each of the plurality of quaternions in polar form, circuitry configured to generate a single-qubit quaternion state at a quantum pixel, using a normalized imaginary part of the quaternion and an angular form of the grayscale image of the color image. circuitry configured to generate a quantum superposition of the quaternion 2-qubit states to form a quantum representation of the color image, and circuitry configured to reconstruct the color image from a measurement of the quantum superposition state of a quantum representation of the color image with (r+s+1) qubits.

### BRIEF DESCRIPTION OF THE DRAWINGS

The details of the present invention, both as to its structure and operation, can best be understood by referring to the accompanying drawings, in which like reference numbers and designations refer to like elements.

FIG. 1 is a schematic diagram of the circuit with the CNOT operation.

FIG. 2 is a schematic diagram of a generic 4-qubit circuit with two CNOT operations based inventive system.

FIG. 3 is a schematic diagram of a generic 4-qubit circuit with two CNOT operations.

FIG. 4 is a schematic diagram of a circuit element for the 2-CNOT operation.

FIG. 4 is a schematic diagram of a circuit element for the 2-CNOT operation.

FIG. 5 is a schematic diagram of a quantum circuit element for the 2-CNOT operation.

FIG. 6 is a schematic diagram of the first 4-qubit circuit with separation of duplicated qubits.

FIG. 7 is a schematic diagram that illustrates the second 4-qubit circuit with separation of duplicated qubits.

FIG. 8 is a schematic diagram that illustrates the block structuring numbering for the 8×8 image.

FIG. 9 is a schematic of a mapping of the integer interval [0,255] into the quarter circle.

FIG. 10 is a schematic diagram that illustrates the mapping of the interval [0,255] into the quarter circle for the grayscale image.

FIG. 11 is a schematic diagram that illustrates the mapping of a color (RGB model) image into [0,255] interval.

FIG. 12 is an original (flower) image and its energy equalization.

FIG. 13 is another exemplary (Tree) image and its energy equalization.

FIG. 14 is a scheme of transformation from three complex subspaces: (a) The threefold complex plane C\hat{ }3 of colors in the RGB model and (b) the 4-D space of quaternions for the model of color images with nonzero grayscale components.

FIG. 15 is a schematic diagram that illustrates a unit square representing the 2-qubit state of the quaternion image at a single pixel.

FIG. 16 is a schematic diagram that illustrates the block diagram of quantum imaging.

FIG. 17 is an exemplary flow diagram of quaternion (or color) image reconstruction.

FIG. 18 is an exemplary block diagram of a classical computer system, in which processes involved in the embodiments described herein may be implemented.

### DETAILED DESCRIPTION

Embodiments may provide techniques by which qubits may be copied and observed in a quantum computing system, as well as for techniques by which images may be represented in quantum computing systems. Embodiments may include techniques for copying qubit system followed by separation of the qubits so that they may be observed. In embodiments, a quantum copying/cloning qubits system may include, for example, two quantum circuits with two CNOT operations each, which generate the duplicated qubits in two qubits of the calculated 4-qubit state. Embodiments may include techniques for generating a discrete data (signals and images) multi-qubit representation of the signal representation system. Embodiments may include techniques for generating color quantum models. Embodiments may include techniques for providing a quaternion quantum image processing system.

Qubit Copying

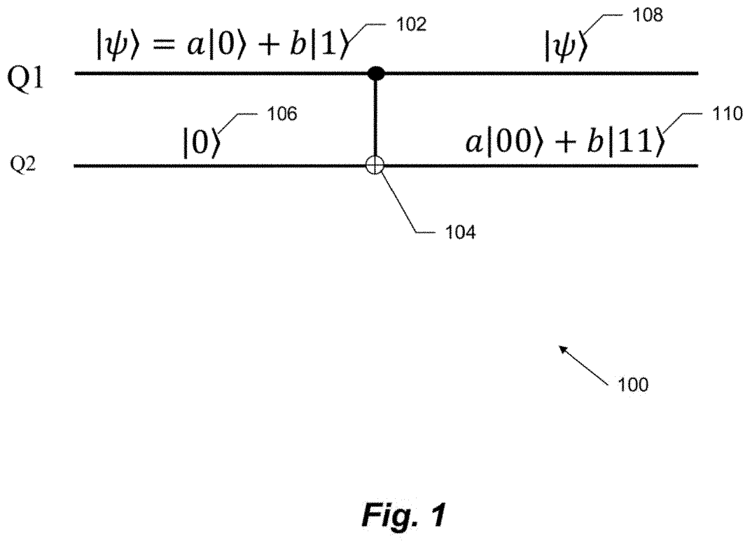

To begin, the simple quantum circuits with two CNOT operations may be analyzed. Two quantum circuits that allow for observing the duplicated qubit states may be described. Formal mathematics may be used for a brief discussion of the problem of copying the qubit. FIG. 1 is an illustration of a circuit 100 with the CNOT operation. Consider one qubit in the state |ψ [symbol] =a|ψ [symbol] +b|1) 102 with the required condition that |α|²+|b|²=1. The duplicated copy of this state is the 2-qubit state

|ψ² [symbol] [symbol] |ψ [symbol] |ψ [symbol] =a²|00 [symbol] +b²|11 [symbol] +ab|01 [symbol] +ab|10 [symbol] . (1)

When applying the CNOT operator (X) 104 with control qubit |ψ [symbol] 102 and controlling (target) state |0 [symbol] 106, the result is the 2-qubit state

|φ [symbol] [symbol] X[|ψ [symbol] ,|0 [symbol] ]=X[a|0 [symbol] +b|1 [symbol] ,|0 [symbol] ]=a|00 [symbol] +b|11 [symbol] , (2)

as it is illustrated in FIG. 1. This operation changes the qubit state |0 [symbol] to |1 [symbol] , when the control qubit is 11), i.e., X[|1 [symbol] , |0 [symbol] ]=|1 [symbol] |1 [symbol] =|11 [symbol] .

Except for the cases when a=0 and b=0, the states |ψ² [symbol] and |φ [symbol] are different. Thus, the qubit in its general state is not copying by this circuit.

Quantum Circuits with Two CNOT. Consider the CNOT operator with the control qubit |ψ [symbol] 202 and the second input being the obtained 2-qubit state |φ [symbol] . It is assumed that the target qubit is the second qubit of |φ [symbol] . The result of this operation is

$${X [ \vert ψ 〉 , \vert ϕ 〉 ]}_{2} = {X [ a \vert 0 〉 + b \vert 1 〉 , a \vert 00 〉 + b \vert 11 〉 ]}_{2} = {X [ a \vert 0 〉 , a \vert 00 〉 + b \vert 11 〉 ]}_{2} + {X [ b \vert 1 〉 , a \vert 00 〉 + b \vert 11 〉 ]}_{2} == ( {a}^{2} \vert 000 〉 + ab \vert 011 〉 ) + ( ba \vert 101 〉 + {b}^{2} \vert 110 〉 ) = ( {a}^{2} \vert 000 〉 + {b}^{2} \vert 110 〉 ) + ( ba \vert 101 〉 + ab \vert 011 〉 ) . \qquad ( 3 )$$

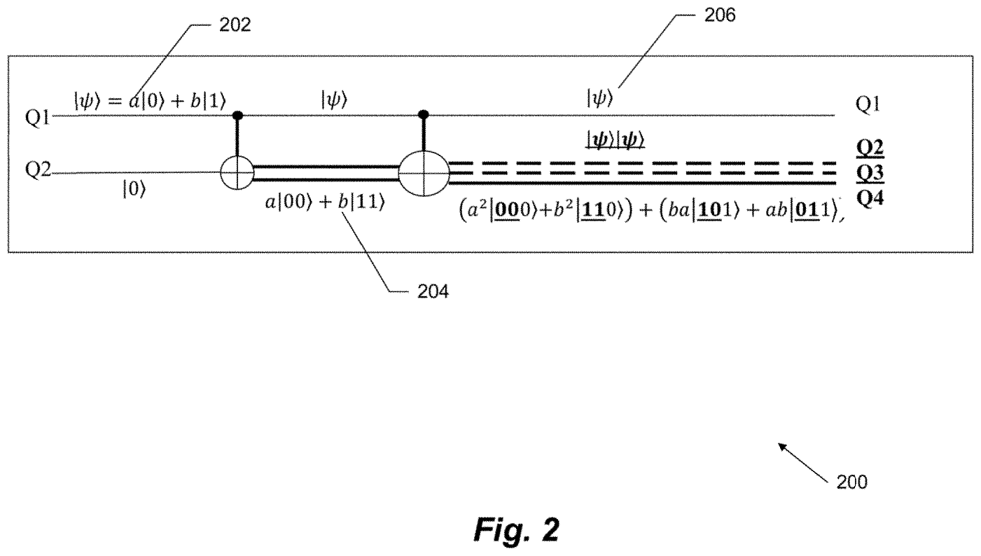

The circuit 200 for calculating this state, a 4-qubit circuit with two CNOT operations, is shown in FIG. 2. The result of the calculation is the 4-qubit state with the first qubit |ψ [symbol] and X[|ψ [symbol] , |φ [symbol] )]₂ in the next three qubits.

Comparing the obtained equation with Eq. 1, it is seen that the first two qubits of the state X[|ψ [symbol] , |φ [symbol] ]₂ describe the state of the duplicated qubits |ψ² [symbol] . Thus, the new state contains the information of the duplicated qubits; the quantum concurrency principle works in this circuit. The 2^{nd} and 3^{rd} qubits in the output state of this circuit are separated, the duplicated state |ψ² [symbol] may be obtained. Thus, in a quantum system, the state of two duplicated qubits may be observed, but mixed with another larger qubit state.

A 2nd Quantum Circuit

It may be noted that, if the target qubit in the second CNOT operation is the first qubit of |φ [symbol] , the following 3-qubit state may be obtained:

$${X [ \vert ψ 〉 , \vert ϕ 〉 ]}_{1} = {X [ a \vert 0 〉 + b \vert 1 〉 , a \vert 00 〉 + b \vert 11 〉 ]}_{1} = {X [ a \vert 0 〉 , a \vert 00 〉 + b \vert 11 〉 ]}_{1} + {X [ b \vert 1 〉 , a \vert 00 〉 + b \vert 11 〉 ]}_{1} == ( {a}^{2} \vert 000 〉 + ab \vert 011 〉 ) + ( ba \vert 110 〉 + {b}^{2} \vert 101 〉 ) = ( {a}^{2} \vert 000 〉 + ba \vert 110 〉 ) + ( ab \vert 011 〉 + {b}^{2} \vert 101 〉 ) . \qquad ( 4 )$$

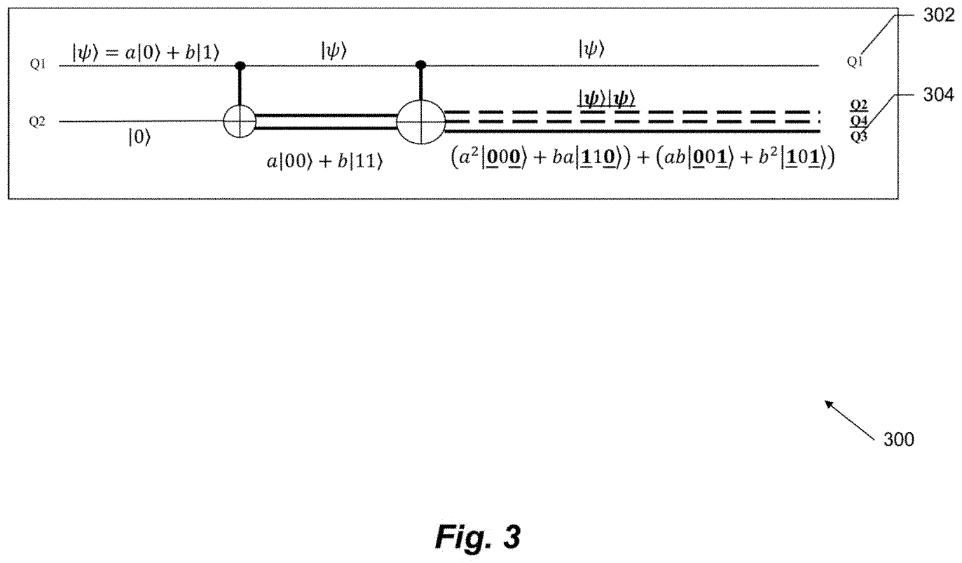

The quantum circuit for these calculations is similar to the circuit in FIG. 2 and shown in FIG. 3, which is also a 4-qubit circuit 300 with two CNOT operations. It may be seen that two qubits of the state X[|ψ [symbol] , |φ [symbol] ]₁, namely qubits number 1 302 and 3 304, describe the duplicated qubits |ψ² [symbol] . Thus, if the 2^{nd} and 4^{th} qubits in the output state of this circuit are separated, |ψ² [symbol] may be obtained.

The above circuits may be used as a part of a large quantum circuit, wherein the duplicated qubits are required in some stages of computing. In this case, there is no need to measure the duplicated qubits.

Measurement of the 4-Qubit State

Analyzing the 3-qubit states in Eqs. 3 and 4, the above presented above two quantum circuits are equivalent, in a sense that they result in the 3-qubit states

|φ_{2,3} [symbol] =(a²|000 [symbol] +b²|110 [symbol] )+(ba|101 [symbol] +ab|011 [symbol] ) (5)

and

|φ_{2,4} [symbol] =(a²|000 [symbol] +ba|110 [symbol] )+(ab|011 [symbol] +b²|101 [symbol] ), (6)

wherein the first two qubits are swapped. This operation is the following permutation of the 3-qubit state:

$$P = ( \begin{matrix}0 & 1 & 2 & 3 & 4 & 5 & 6 & 7 \\ 0 & 2 & 1 & 3 & 4 & 6 & 5 & 7\end{matrix} ) \qquad ( 7 )$$

which can be written in matrix form as

$$P = [ \begin{matrix}1 & 0 & 0 & 0 & 0 & 0 & 0 & 0 \\ 0 & 0 & 1 & 0 & 0 & 0 & 0 & 0 \\ 0 & 1 & 0 & 0 & 0 & 0 & 0 & 0 \\ 0 & 0 & 0 & 1 & 0 & 0 & 0 & 0 \\ 0 & 0 & 0 & 0 & 1 & 0 & 0 & 0 \\ 0 & 0 & 0 & 0 & 0 & 0 & 1 & 0 \\ 0 & 0 & 0 & 0 & 0 & 1 & 0 & 0 \\ 0 & 0 & 0 & 0 & 0 & 0 & 0 & 1\end{matrix} ] = [ \begin{matrix}1 & 0 \\ 0 & 1\end{matrix} ] ⊗ [ \begin{matrix}1 & 0 & 0 & 0 \\ 0 & 0 & 1 & 0 \\ 0 & 1 & 0 & 0 \\ 0 & 0 & 0 & 1\end{matrix} ] .$$

Here, the operation ⊗ denotes the tensor product (or, the Kronecker product) of matrices.

Thus, the result is:

|φ_{2,4} [symbol] =P|φ_{2,3} [symbol] , |φ_{2,3} [symbol] =P|φ_{2,4} [symbol] . (8)

Therefore, the first 3-qubit state |φ_{2,3} [symbol] , that is the state that is calculated by the quantum circuit given in FIG. 2 may be used.

Consider the 2-qubit state |ψ² [symbol] . When measuring its first qubit and it is |0 [symbol] , the new state will be |(ψ²)₀ [symbol] =a²|00 [symbol] +ab|01 [symbol] or after normalizing the coefficients of this state, it will be

|(ψ²)₀)=a|00 [symbol] +b|01 [symbol] =|0 [symbol] +b|1 [symbol] )=|0 [symbol] |ψ [symbol] . (9)

In the case when the measured first qubit is 11), the new state will be |(ψ²)₁ [symbol] =ab|10 [symbol] +b²|11 [symbol] , or

|(ψ²)₁ [symbol] =ab|10 [symbol] +b²|11 [symbol] , or |(ψ²)₁ [symbol] =a|10 [symbol] +b|11 [symbol] =|1 [symbol] (a|0 [symbol] +b|1 [symbol] )=|1 [symbol] |ψ [symbol] , (10)

after coefficient normalization.

Thus, during the measurement of the first qubit, the following outcomes may be obtained:

$$\vert {ψ}^{2} 〉 = {a}^{2} \vert 00 〉 + {b}^{2} \vert 11 〉 + ab \vert 01 〉 + ab \vert 10 〉 {\to }^{ Measurement } \{ \begin{matrix}outcome 0 , & \vert 0 〉 ψ 〉 , \\ outcome 1 , & \vert 1 〉 \vert ψ 〉 .\end{matrix} \qquad ( 11 )$$

The 2-qubit state |ψ² [symbol] is not entangled. Regardless of the outcome of the first qubit, the second qubit is in the original state |ψ [symbol] .

Now, consider the 3-qubit state in Eq. 3 that includes the duplicated qubit

|φ_{2,3} [symbol] =(a²|000 [symbol] +b²|110 [symbol] )+(ba|101 [symbol] +ab|011 [symbol] ) (12)

When measuring the first qubit and the result is |0 [symbol] , the new state will be a²|000 [symbol] +ab|011 [symbol] , which after coefficient normalization should be written as a|000 [symbol] +b|011 [symbol] . After separating the first two qubits from this state, we obtain the measurement

|(ψ²)₀ [symbol] =a|00 [symbol] +b|01 [symbol] =|0 [symbol] (a|0 [symbol] +b|1 [symbol] )=|0 [symbol] |ψ [symbol] . (13)

The required separation of qubits can be performed by CNOT operation applied on the 2^{nd} (control) and 3^{rd} (target) qubits,

CNOT_{2,3}:a|000 [symbol] +b|011 [symbol] →a|000 [symbol] +b|010 [symbol] =(a|00 [symbol] +b|01 [symbol] )|0 [symbol] . (14)

In the case when the measured first qubit in the 3-qubit state is in the basic state |ψ [symbol] , the new state will be b²|11 [symbol] +ba|101 [symbol] which is after renormalization of coefficients will be written as b|110 [symbol] +a|101 [symbol] . After separation by the same CNOT2,3 operations, the first two qubits are in the state that corresponds to the measurement

|(ψ²)₁ [symbol] =a|10 [symbol] +b|11 [symbol] =|1 [symbol] (a|0 [symbol] +b|1 [symbol] )=|1 [symbol] |ψ [symbol] . (15)

Both results of the measurement, (13) and (15), match the results of the measurement of the duplicated qubits in (11). Thus, the probability of observing the first two qubits in the 3-qubit state |φ_{2,3} [symbol] is the same as for the duplicated qubits. The above circuit exhibits entanglement Error! Reference source not found.; the duplicated qubits are observed together with the 3^{rd} qubit in Eq. 3.

Separation of the Duplicated Qubits

To separate the duplicated qubit state |ψ² [symbol] from the obtained 3-qubit state in the circuit of FIG. 3

|φ_{2,3} [symbol] =(a²|000 [symbol] +b²|100 [symbol] )+(ba|101 [symbol] +ab|011 [symbol] ),

consider the transformation shown in Table 1. The 2-Controlled-NOT gate is used with the target qubit number 3. The result of this operation is the duplicated qubit and qubit number 3 which is only in the basic state |ψ [symbol] . Thus, the measurement of the last qubit (which is only in this basic state with probability 1) allows for obtaining the duplicated qubits.

TABLE 1
Separation of the duplicated state from qubit number 3.

| Input | | | Qubit |
|---|---|---|---|
| state | 2Controlled-NOT Gate on Q₃ | Qubits # 1 and 2 | #3 |
| \|φ_{2, 3} [symbol] | a²\|000 [symbol] + b²\|110 [symbol] + ba\|100 [symbol] + | a²\|00 [symbol] + b²\|11 + ba\|10 [symbol] + | \|0 [symbol] |
| | ab\|010 [symbol] | ab\|01 [symbol] | |

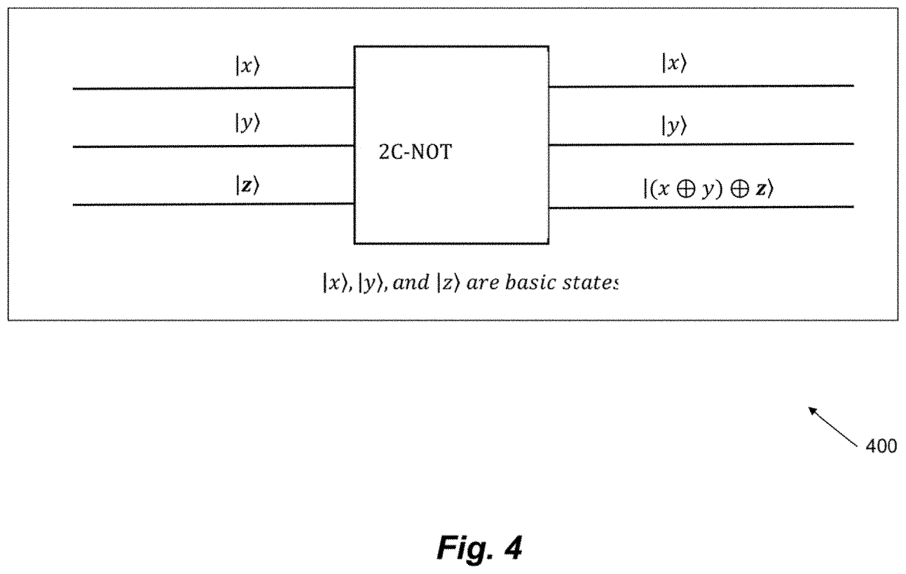

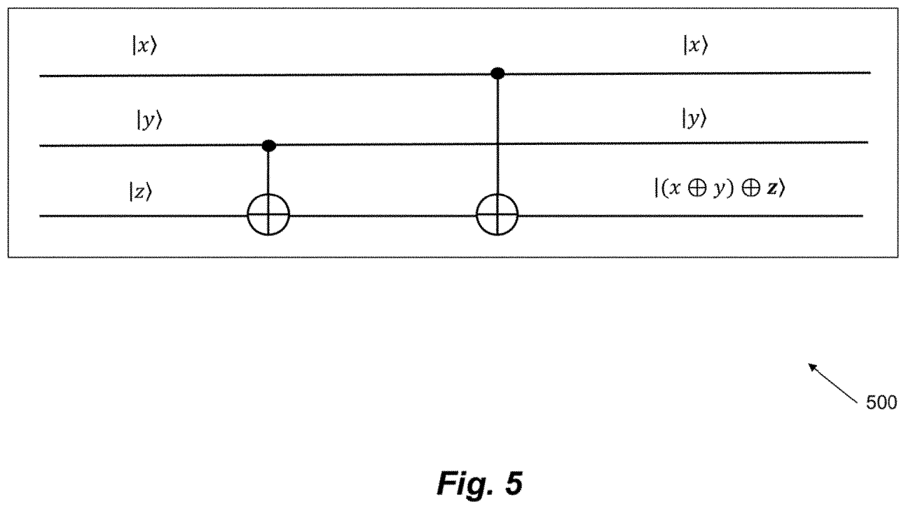

The above 2-CNOT gate is used to process the last qubit with the sum of the first two controlling qubits. An embodiment of a circuit 400 of the gate element for the 2-CNOT operation is shown in FIG. 4. An embodiment of a quantum circuit element 500 for the 2-CNOT operation is shown in FIG. 5

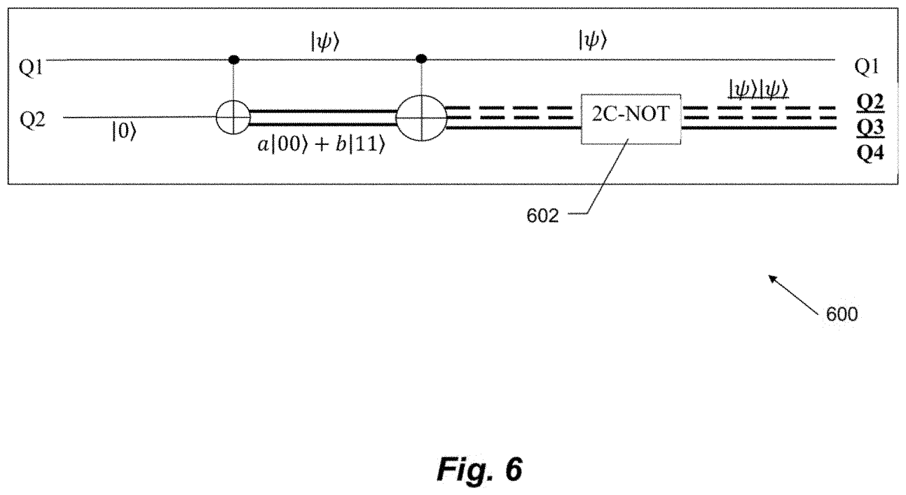

The full quantum circuit 600 that is completed with the separation of duplicated qubits is shown in FIG. 6. The target qubit for the second CNOT operation 602 is the second qubit of the 2-qubit state |φ [symbol] .

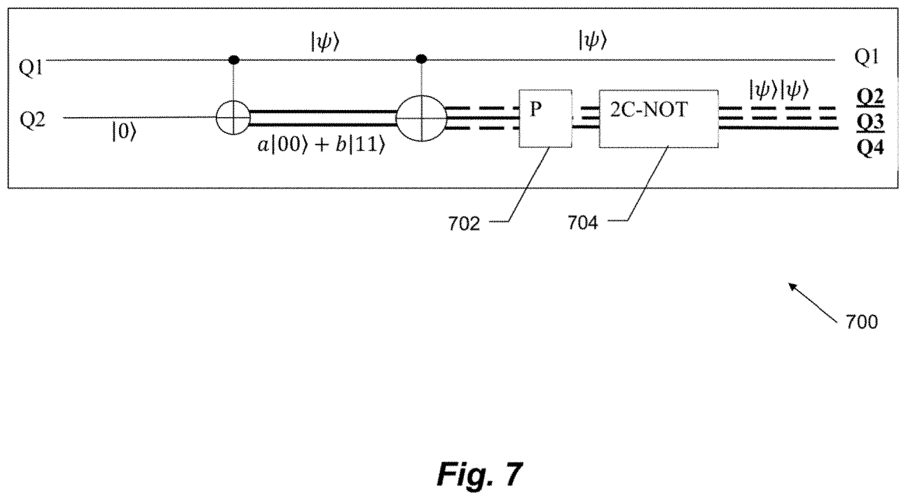

The second quantum circuit given in FIG. 3, after adding the elements of permutation 702 and 2C-NOT 704 operation, for separating the duplicated qubits, is shown in FIG. 7. The target qubit for the second CNOT operation in this circuit is the first qubit of the 2-qubit state |φ [symbol] .

The accurate measurement of the calculated multi-qubit state in a quantum computer is performed with classical calculations and is a difficult task to be solved. Unlike the calculation in a traditional computer, in quantum computing, a very large number of measurements are required, and the circuit should be run repeatedly. Such measurement may be carried out physically in different quantum systems, as is well-known.

### The Second Embodiment

Image and video representation, retrieval, analysis, and storage is quite easy to perform on classical computers, however, is very challenging using quantum states. For example, should the colors be represented so as to use the minimum number of qubits. Typically, represent colors using a quantum circuit comprises two main steps 1) creating the superposition of all states using the cascaded Hadamard procedure, which was initially in the zero states, and performing controlled rotation operations, which encode the information of color with each state. This yields a representation in which final state of the qubits as a superposition where each bitstring represents the position of a pixel, tensored with one qubit which is used for encoding the information of color.

Image Representation (State of the Art)

Models with Quantum pixels: a quantum pixel may be used for a discrete image f={f_{n,m}} of size N×M, N=2^{r}, M=2^{s}, r,s>1, with the range of intensities in the interval of integers [0,255]. The quantum pixel(n, m) may be defined by the following transform to the state of superposition of a single qubit:

$${f}_{n , m} \to \vert {f}_{n , m} 〉 = \frac{1}{\sqrt{255}} [ \sqrt{255 - {f}_{n , m}} \vert 0 〉 + \sqrt{{f}_{n , m}} \vert 1 〉 ] . \qquad ( 16 )$$

Defining the angle by

$${ϑ}_{n , m} = {cos}^{- 1} \sqrt{1 - \frac{{f}_{n , m}}{255}} , \qquad ( 17 )$$

the quantum pixel state can be written as the qubit

|f_{n,m} [symbol] =cos ϑ_{n,m}|0 [symbol] +sin ϑ_{n,m}|1 [symbol] . (18)

Thus, one qubit can be assigned to each pixel. The quantum superposition state of NM quantum pixels for the entire image can be presented by the following state of (r+s+1) qubits:

$$\vert \check{f} 〉 = \frac{1}{\sqrt{NM}} {\sum }_{m = 0}^{M - 1} {\sum }_{n = 0}^{N - 1} \vert {f}_{n , m} 〉 ⊗ \vert n , m 〉 == \frac{1}{\sqrt{NM}} {\sum }_{m = 0}^{M - 1} {\sum }_{n = 0}^{N - 1} [ cos {ϑ}_{n , m} \vert 0 〉 + sin {ϑ}_{n , m} \vert 1 〉 ] ⊗ \vert n , m 〉 . \qquad ( 19 )$$

For integers n=0, 1, . . . , N−1 and m=0, 1, . . . , M−1, the states |n [symbol] and |m [symbol] are the quantum computational basis states which are written in their binary forms, and

|n [symbol] |m [symbol] =|n,m [symbol] =|n [symbol] ⊗|m)=|nᵣ₋₁nᵣ₋₂ . . . n₁n₀ [symbol] ⊗|mₛ₋₁mₛ₋₂ . . . m₁m₀ [symbol] (20)

Here, the operation ⊗ denotes the tensor product. The image representation in Eq. 19 requires (r+s) qubits for all pixel coordinates paired with one additional qubit, which carries the information of the intensity of the image in the form of angles.

The state of a pixel (n n) may also be defined as

q_{n,m}=a_{n,m}|n [symbol] |m [symbol] , (21)

where the coefficient a_{n,m} is the value f_{n,m} of the image after the normalization,

$${a}_{n , m} = \frac{{f}_{n , m}}{E} , E = \sqrt{{\sum }_{n = 0}^{N - 1} {\sum }_{m = 0}^{M - 1} {f}_{n , m}^{2}} . \qquad ( 22 )$$

Therefore, the image can be presented by the NM-quantum superposition state

$$\vert \check{f} 〉 = {\sum }_{m = 0}^{M - 1} {\sum }_{n = 0}^{N - 1} {q}_{n , m} = {\sum }_{m = 0}^{M - 1} {\sum }_{n = 0}^{N - 1} {a}_{n , m} \vert n , m 〉 . \qquad ( 23 )$$

This representation requires (r+s) qubits, while the discrete image with 8 bits intensities uses 8NM bits.

QLM Model: Typical representations of images in qubits are similar in that they represent as a qubit in each pixel. For example, one qubit may be described as

|φ [symbol] =c₀|0 [symbol] +c₁|1 [symbol] =cos ϑ|0 [symbol] +e^{iγ} sin ε|1 [symbol] (24)

as the state, or a point in the unit sphere Error! Reference source not found.. Here, ϑ and γ are angles from the interval [0, π/2]. Coefficients c₀ and c₁ can be selected in different ways, but with the required condition that |c₀|²+|c₁|²=1.

In the qubit lattice model (QLM) of images, a representation that is similar to (19) is used Error! Reference source not found.. The grayscale or color image f=f_{n,m} of size N×M is presented by the matrix with states

Q={cos ϑ_{n,m}|0 [symbol] +e^{iγ} sin ϑ_{n,m}|1 [symbol] ; n=0:(N−1), m=0:(M−1)}, (25)

Here, the values of grays or colors may be written/encoded in angles ϑ_{n,m}, and γ is a constant. The quantum state of such data may be written as

$$\vert \check{f} 〉 = \frac{1}{\sqrt{NM}} {\sum }_{m = 0}^{M - 1} {\sum }_{n = 0}^{N - 1} ( cos {ϑ}_{n , m} \vert 0 〉 + {e}^{{i}_{γ}} sin {ϑ}_{n , m} \vert 1 〉 ) ⊗ \vert n , m 〉 . \qquad ( 26 )$$

The phase factor e^{iγ} is added to the qubit state for each pixel. This representation requires (r+s+1) qubits, as in the model described in (19) with quantum pixels.

FRQI Model Error! Reference source not found.: In the flexible representation for quantum images (FRQI) model, a discrete image of size 2^{r}×2^{r} is written into a 4^{r}-dimensional vector and then presented as the following 4^{r}-qubit state:

$$\vert \check{f} 〉 = \frac{1}{{2}^{r}} {\sum }_{n = 0}^{{4}^{r} - 1} ( cos {ϑ}_{n} \vert 0 〉 + sin {ϑ}_{n} \vert 1 〉 ) ⊗ \vert n 〉 , \qquad ( 27 )$$

where |n [symbol] are computational basis quantum states and the information of image colors is written into angles ϑₙ. This qubit representation is similar to other representations when γ=0. The 4^{r}-dimensional vector may be composed by all rows or all columns of the image, as well as by blocks. This is the main difference between FRQI model and the model with the quantum pixels, which is given in Eq. (19).

Color Image Models Error! Reference source not found.: The concept of a quantum pixel in a color image may be modeled as, at each pixel number n, the two components are normalized, for instance, the red and green components, and then moved into the interval [−1, 1], as r→2r−1 and g→2g−1. The corresponding angles are calculated by φᵣ=sin⁻¹(2r−1) and φ_{g}=sin⁻¹(2g−1). The qubit pixel may be defined as

q=qₙ=z₀|0 [symbol] +z₁|1 [symbol] , where z₀=a_{n,0}=\sqrt{1−b²}e^{iφ}^{ᵣ}, z₁=z_{n,1}=be^{iφ}^{_{g}}. (28)

Thus, the probability of measuring basic states in this qubit is defined by the blue color; |z₀|=\sqrt{1−b²} and |z₁|=b. The transformation of colors (r, g, b)→(z₀, z₁) is invertible:

$$b = \vert {z}_{1} \vert \neq 0 , 1 , sin {ϕ}_{g} = Imag \frac{{z}_{1}}{b} , g = \frac{sin {ϕ}_{g} + 1}{2} , and$$

$$sin {ϕ}_{r} = Imag \frac{{z}_{0}}{\sqrt{1 - {b}^{2}}} , r = \frac{sin {ϕ}_{r} + 1}{2} .$$

The 4^{r}-dimensional vector presents the color image by the following quantum state:

$$\vert \check{f} 〉 = \frac{1}{{2}^{r}} {\sum }_{n = 0}^{{4}^{r} - 1} ( {z}_{n , 0} \vert 0 〉 + {z}_{n , 1} \vert 1 〉 ) ⊗ \vert n 〉 . \qquad ( 29 )$$

This representation of the image requires (2r+1) qubits, as in the model QLM.

RKM Model [6]: In the Real Ket Model (RKM), the discrete image f_{n,m} of square size N×N=2^{r}×2^{r} is divided consequently down into 4 equal parts, and therefore the image can be presented as

$$\vert \check{f} 〉 = {\sum }_{{n}_{1} , {n}_{2} , … , {n}_{r} = 1 , 2 , 3 , 4} {c}_{{n}_{1} , {n}_{2} , … , {n}_{r}} \vert {n}_{1} , {n}_{2} , … , {n}_{r} 〉 . \qquad ( 30 )$$

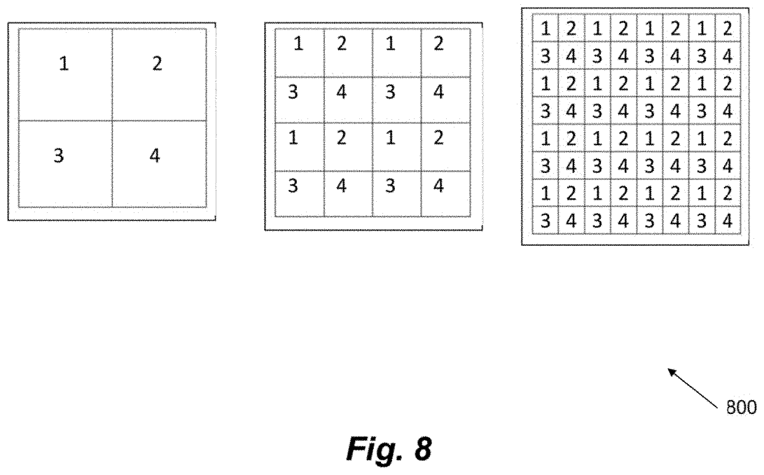

The intensities f_{n,m} of the image are stored in the coefficients Error! Reference source not found. Such numbering of pixels allows for using only r qubits for the image; and each such qubit is a superposition of 4 values. The scheme of block structuring numbering 800 for an 8×8 image is shown in FIG. 8. In this representation, for example, the coefficient in the pixel (3,2) is numbered as (1,4,3), and the coefficient in the pixel (6,5) is numbered as (4,3,2). Therefore, the values f_{3,2} and f_{6,5} are stored as c_{1,4,3}|143) and c_{4,3,2}|432), respectively. Here c_{1,4,3} and c_{4,3,2} are amplitudes that are defined from the values f_{3,2} and f_{6,5}, respectively. For instance, these coefficients can be considered c_{1,4,3}=a_{3,2} and c_{4,3,2}=a_{6,5} when using the amplitudes calculated by Eq. (22).

NEQR and GQIR Models [8, 11, 12]: Such models extend the dimension NM of states in the quantum representation of images. The Novel Enhanced Quantum Representation (NEQR) was proposed for the discrete image of size N×M=2^{r}×2^{s}, with integers r and s>1 Error! Reference source not found.. This method may be extended for other sizes of images by the Generalized Quantum Image Representation model (GQIR)) Error! Reference source not found.Error! Reference source not found.. The qubit states of pixels are nested into the higher dimension basic states, by using the operation of a tensor product with the intensity (or brightness) of the image, which is written in the binary form as a multi-qubit state. For example, if the range of the image is [0,255], i.e., with 8 bits, the value of the image at pixel (n, m) can be written in binary form

f_{n,m}→[(f_{n,m})₇,(f_{n,m})₆, . . . ,(f_{n,m})₁,(f_{n,m})₀]

and the state in this pixel is defined as

$$\vert {q}_{n , m} 〉 = \vert {( {f}_{n , m} )}_{7} , {( {f}_{n , m} )}_{6} , … , {( {f}_{n , m} )}_{1} , {( {f}_{n , m} )}_{0} 〉 ⊗ \vert n , m 〉 = \vert {( {f}_{n , m} )}_{7} , {( {f}_{n , m} )}_{6} , … , {( {f}_{n , m} )}_{1} , {( {f}_{n , m} )}_{0} , n , m 〉 . \qquad ( 31 )$$

Thus, the image with 8-bit intensity can be presented as

$$\vert \check{f} 〉 = \frac{1}{\sqrt{{2}^{r + s}}} {\sum }_{m = 0}^{M - 1} {\sum }_{n = 0}^{N - 1} \vert {q}_{n , m} 〉 \qquad ( 32 )$$

and that requires (r+s+8) qubits.

NASS and NASSTC Models Error! Reference source not found.Error! Reference source not found.: In the Normal Arbitrary Superposition State (NASS) model, each color of the image f_{n,m}=(r_{n,m}, g_{n,m}, b_{n,m}) is considered as the number in the 256^{th} representation,

c=c(n,m)=256²r_{n,m}+256g_{n,m}+b_{n,m}. (33)

The base of this presentation, 256, is chosen for images in the standard range [0,255] of grays. This representation corresponds to the system with a 24-bit or 3-byte memory word. In other words, the RGB image is presented as the grayscale image with intensities in the range [0, 256³−1]. The number of grays is very large, 256³=16777216. One can note that many similar colors are far apart in such an image. For example, the colors (100, 20, 10) and (101, 21, 10) are located at a distance of 256²+256=65792 from each other. Then, the grayscale image c(n, m) of size 2^{r}×2^{r} pixels, as the 4^{r}-dimensional vector with angle components c(i)=c(n, m), where i=n2^{r}+m, is represented by the following superposition of 2r qubits:

$$\vert {\check{f}}_{A} 〉 = {\sum }_{i = 0}^{{4}^{r} - 1} {ϑ}_{c ( i )} \vert i 〉 . \qquad ( 34 )$$

Here, the coefficients are

$${ϑ}_{c ( i )} = c ( i ) / \sqrt{{\sum }_{i = 0}^{{4}^{r} - 1} {c}^{2} ( i )} , c ( i ) ∈ \{ 0 , 1 , 2 , … , {256}^{3} - 1 \} . \qquad ( 35 )$$

The amplitudes of states determine a probabilistic representation of the quantum image in (30). From the 256^{th} representation of colors, which is given in Eq. (28), it may be noted that colors with red components, even of low intensity, have a very high probability of measurement compared to green and blue. For instance, the pixels with any pure red value, even small, for instance (7,0,0), have a probability that is proportional to the number (7×256²)², whereas the strong pure green, for instance (0,200,0) has the number (200×256)², and for the pure blue color, for instance (0,0,220), such a number is much smaller, (220)². This may mean that after measuring states of the superposition of 2r qubits in (30), the color image is most likely to be a red image with a few pixels or without it with green and blue colors. In addition, the starting Eq. (28) in NASS is written for 8-bit images, and many images in medical imaging and other applications use 10, 12, and 16-bit image formats. For 16-bit images, the numbers 2⁸=256 in (28) will be changed by 2¹⁶=65536 and the range of the grayscale image in 65536^{th} representation will be very large, [0, 2^{16×3}−1].

For RGB color images, in the extension of NASS with three components (NASSTC) Error! Reference source not found., the standard basic states of pixels |i [symbol] are united with an incomplete 2-qubit state of colors as follows:

$$\vert {\check{f}}_{C} 〉 = {\sum }_{i = 0}^{{4}^{r} - 1} [ {c}_{R} ( i ) \vert 10 〉 + {c}_{G} ( i ) \vert 01 〉 + {c}_{B} ( i ) \vert 11 〉 ] \vert i 〉 . \qquad ( 36 )$$

Here, the coefficients c_{R}(i) for the red component of the image (r(i), g(i), b(i)) is calculated by

$$\begin{matrix}{c}_{R} ( i ) = r ( i ) / \sqrt{{\sum }_{i = 0}^{{4}^{r} - 1} [ {r}^{2} ( i ) + {g}^{2} ( i ) + {b}^{2} ( i ) ]} , & ( 37 ) \\ r ( i ) , g ( i ) , b ( i ) ∈ \{ 0 , 1 , 2 , … , 255 \} . & \end{matrix}$$

For the green and blue components, the corresponding coefficients c_{G}(i) and c_{B}(i) are calculated similarly. This representation of the RGB color image requires (2r+2) qubits.

It is to be noted that the quantum representation given in Eq. (23) is simple and does not require additional qubits for the color. For comparison, the quantum representation in Eq. (19) requires a single qubit for the color.

There is redundancy in the color qubit in Eq. (19) at each pixel. The information of the image in the form of angle is written into both basic states |ψ [symbol] and |1 [symbol] of the color qubit. The same comments apply to many other methods of image representation (including the below methods QLM, FRQI, Color Image Model, and NASSTC) when the color at pixel is encoded into a single qubit, not a basic state.

The angular presentation of the color in single-qubit has limitations in application, which are 1) the image cannot be accurately recovered (determined) by using a finite number of measurement, 2) basic operations on images is difficult to accomplish on quantum images, and 3) practical limitation on the number of colors/positions that can be physically executable.

Embodiments may provide a new approach for representing discrete signals and images in quantum computing, by mapping the input data into the unit circle. For color images, the primary color components may be mapped into different parts of the unit circle to get the quantum image representation. Such representation leads to the concept of the Fourier transform qubit representation of images. For RGB color images, embodiments may include two models of representation with the concept of the 3-point DFT of color qubits. A similar Fourier transform qubit representation of images in quantum computing can be described in other color models, such as the XYZ, CMY(K), and YCbCr models Error! Reference source not found.Error! Reference source not found.. Embodiments may be used in quantum imaging together with the existent models of image representation.

Fourier Transform Quantum Representation of Signals

Embodiments may involve converting the signal into another signal and then representing that signal as a multi-qubit state. It may be assumed that all signal/image values are valuable and counted in the same way, and in measurements, they will have the same probability of representing the image. For example, consider the following transformation of the real signal in the range of [0,255]; 8-bit intensity is the standard format for many grayscale images. Let the signal fₙ of length N=2′, r>1, be transformed as

fₙ→T[fₙ]=e^{i2πf}^{ₙ}^{/4×256}, n=0:(N−1). (38)

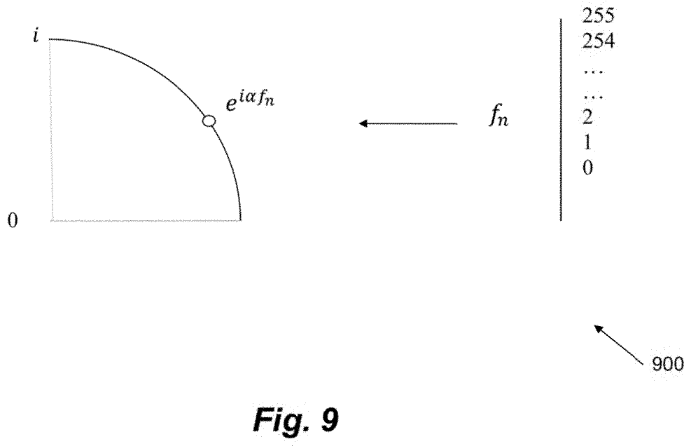

Values of the signal T[fₙ] are different. The additional factor of 4 may be used to have all values of the transform in the first quarter circle. An example 900 of the transformation of the integer interval [0,255] into the quarter circle is shown FIG. 9. Defining the constant α=2π/1024, the transform can be written as T[fₙ]=e^{iαf}^{ₙ}.

Now, consider the representation of the signal in the form of the following r-qubit state:

$$\vert {f}^{⋁} 〉 = \frac{1}{\sqrt{N}} [ {e}^{i α {f}_{0}} \vert 0 〉 + {e}^{i α {f}_{1}} \vert 1 〉 + {e}^{i α {f}_{2}} \vert 2 〉 + … + {e}^{i α {f}_{N - 1}} \vert N - 1 〉 ] . \qquad ( 39 )$$

In this representation, which we call the Fourier transform quantum representation (FTQR); all states have the same probability

$${\vert \frac{1}{\sqrt{N}} {e}^{i α {f}_{k}} \vert}^{2} = \frac{1}{N} , k = 0 \text{:} ( N - 1 ) .$$

The representation of the signal f requires r qubits,

$$\vert {f}^{⋁} 〉 = \frac{1}{E} [ {f}_{0} \vert 0 〉 + {f}_{1} \vert 1 〉 + {f}_{2} \vert 2 〉 + … + {f}_{N - 1} \vert N - 1 〉 ] ,$$

where the coefficients of the basic states are the normalized values of the signal. Here, E is the square root of the signal energy,

E²=f₀²+f₁²+ . . . +f_{N-1}².

### Example 1

The signal f=(f₀, f₁, f₂, . . . , f₇)=(2, 1, 0, 1, 2, 4, 3, 1) with 3-bit values can be written in the Fourier transform qubit representation as

$$\begin{matrix}\vert {f}^{⋁} 〉 = \frac{1}{\sqrt{8}} [ {e}^{i α 2} \vert 0 〉 + {e}^{i α} \vert 1 〉 + \vert 2 〉 + {e}^{i α} \vert 3 〉 + {e}^{i α 2} \vert 4 〉 + {e}^{i α 4} \vert 5 〉 + {e}^{i α 3} \vert 6 〉 + {e}^{i α} \vert 7 〉 ] \\ = \frac{1}{\sqrt{8}} [ \vert 2 〉 + {e}^{i α} ( \vert 1 〉 + \vert 3 〉 + \vert 7 〉 ) + {e}^{i α 2} ( \vert 0 〉 + \vert 4 〉 ) + {e}^{i α 3} \vert 6 〉 + {e}^{i α 4} \vert 5 〉 ] .\end{matrix}$$

Here, the constant a=2π/(4×8)=π/16.

This transform has the following properties:

(Inverse transform) The value fₖ of the signal can be reconstructed from the amplitude of state of measurement |k [symbol] as

$$\frac{1}{\sqrt{N}} {e}^{i α {f}_{k}} \to {C}_{k} = cos ( α {f}_{k} ) \to {f}_{k} = \frac{1}{α} {cos}^{- 1} ( {C}_{k} ) . \qquad ( 40 )$$

(Constant Adding) When adding a constant to the signal, for instance fₙ→fₙ+1, while preserving the range of the signal, the qubit superposition states are changed as

$$\vert 〉 = \frac{1}{\sqrt{N}} [ {e}^{i α {f}_{0}} \vert 0 〉 + {e}^{i α {f}_{1}} \vert 1 〉 + {e}^{i α {f}_{2}} \vert 2 〉 + … + {e}^{i α {f}_{N - 1}} \vert N - 1 〉 ] {e}^{i α} = {e}^{i α} \vert {f}^{⋁} 〉 ,$$

and when considering the signal fₙ−1, its r-qubit state is

$$\vert 〉 = \frac{1}{\sqrt{N}} [ {e}^{i α {f}_{0}} \vert 0 〉 + {e}^{i α {f}_{1}} \vert 1 〉 + {e}^{i α {f}_{2}} \vert 2 〉 + … + {e}^{i α {f}_{N - 1}} \vert N - 1 〉 ] {e}^{- i α} = {e}^{- i α} \vert {f}^{⋁} 〉 .$$

In general, given a constant A, the qubit representation of the new signal gₙ=fₙ+A equals

|\check{g} [symbol] =e^{iαA}|\check{f} [symbol] . (41)

(Amplification of the signal) Given a constant B, the representation of the signal gₙ=Bfₙ is

$$\vert {g}^{⋁} 〉 = \frac{1}{\sqrt{N}} [ {e}^{i α B {f}_{0}} \vert 0 〉 + {e}^{i α B {f}_{1}} \vert 1 〉 + {e}^{i α B {f}_{2}} \vert 2 〉 + … + {e}^{i α B {f}_{N - 1}} \vert N - 1 〉 ] .$$

The coefficients of this new r-qubit state are

e^{iαBf}^{ₖ}=(e^{iαf}^{ₖ})^{B}, k=0,1, . . . ,(N−1). (42)

(Sum of signals) The qubit representation of the sum of two signals (fₙ+gₙ) equals

$$\vert 〉 = \frac{1}{\sqrt{N}} {\sum }_{k = 0}^{N - 1} {e}^{i α ( {f}_{k} + {g}_{k} )} \vert k 〉$$

and the coefficients of states of the sum equals the products of coefficients of qubits |\check{f} [symbol] and |\check{g} [symbol] ,

e^{iα(f}^{ₖ}^{+g}^{ₖ}⁾=e^{iαf}^{ₖ}e^{iαg}^{ₖ}, k=0,1, . . . ,(N−1). (43)

(Shift of the signal) The circular shift of the signal, fₙ→f_{n-1 mod N} change the qubit representation of the signals as follows:

e^{iαf}^{ₙ}|n [symbol] →e^{iαf}^{ₙ₋₁}|n [symbol] , n=1,2, . . . ,(N−1), e^{iαf}^{₀}|0 [symbol] →e^{iαf}^{_{N-1}}|0 [symbol] .

Fourier Transform Quantum Representation (FTQR) of Grayscale Images

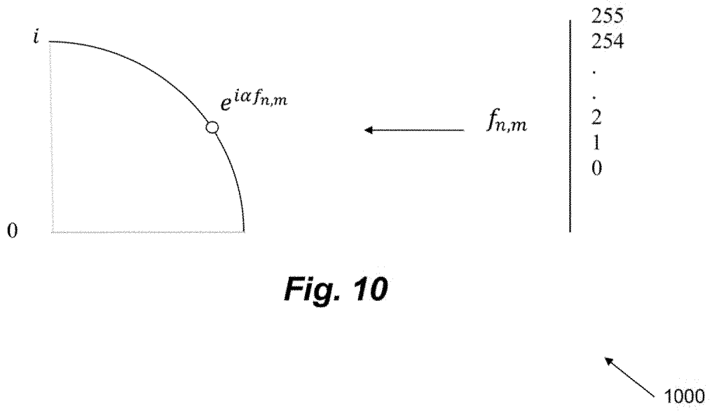

The grayscale image f=f_{n,m} of size N×M=2^{r}×2^{s} in the range of integers [0,255] can be represented by the exponential coefficients in a way that is similar to the one-dimensional signals. An example 1000 of transformation of the interval [0,255] into the quarter circle, for a grayscale image is shown in FIG. 10. The image is transforming as

f_{n,m}→T[f_{n,m}]=e^{iαf}^{_{n,m}}, α=2π/1024, (44)

and then, the (r+s)-qubit Fourier transform representation is defined by the following superposition:

$$\vert {f}^{⋁} 〉 = \frac{1}{\sqrt{N M}} {\sum }_{m = 0}^{M - 1} {\sum }_{n = 0}^{N - 1} T [ {r}_{n , m} ] \vert n , m 〉 = \frac{1}{\sqrt{N M}} {\sum }_{m = 0}^{M - 1} {\sum }_{n = 0}^{N - 1} {e}^{i α {f}_{n , m}} \vert n , m 〉 . \qquad ( 45 )$$

It is to be noted that information on the image in each pixel may be written in the phase-type amplitude. There is no constraint on the size and range of the signal and image when using the FTQR.

FTQR possesses properties, such as the sum, amplification, shifting, that are not available for known methods of signal and image quantum representation.

The calculation of phase-type amplitudes in signal and image representation is simple. These amplitudes can be calculated in advance, and then used by the look-up table method.

In FTQR, all states in the superposition have an equal probability.

FTQR requires the minimum number of qubits for signals and images.

FTQR is an effective tool to process quantum signals and images in the frequency domain.

FTQR has a simple algorithm for signal and image reconstruction, after measuring the superposition state. When measuring |\check{f} [symbol] in (39) and getting the state |n, m [symbol] , it's amplitude e^{iαf}^{_{n,m}}/\sqrt{NM} allows for calculating the value f_{n,m} of the image.

FTQR is not the classical discrete Fourier transform (DFT). The inverse DFT requires knowledge of all components of the transform. For FTQR, the image reconstruction from this representation relates to the measurement of the superposition state, as described above.

Fourier Transform Quantum Representation of Color Images

Embodiment for RGB Color Images

In many applications of color image processing using a traditional computer, the color components of the image may be processed separately Error! Reference source not found.Error! Reference source not found.. Therefore, the above-proposed models of quantum image representation may be applied for each image component, including the Fourier representation. For example, if the image is in the RGB format, then the red, green, and blue components can be represented by the (r+s)-qubit Fourier representation of each. Thus, the following quantum representation may be considered for three-components of the RGB image:

$$\vert {r}^{⋁} 〉 = \frac{1}{\sqrt{N M}} {\sum }_{m = 0}^{M - 1} {\sum }_{n = 0}^{N - 1} T [ {r}_{n , m} ] \vert n , m 〉 , \\ \vert {g}^{⋁} 〉 = \frac{1}{\sqrt{N M}} {\sum }_{m = 0}^{M - 1} {\sum }_{n = 0}^{N - 1} T [ {g}_{n , m} ] \vert n , m 〉 , \\ \vert {b}^{⋁} 〉 = \frac{1}{\sqrt{N M}} {\sum }_{m = 0}^{M - 1} {\sum }_{n = 0}^{N - 1} T [ {b}_{n , m} ] \vert n , m 〉 .$$

Here, the transform is T[f_{n,m}]=e^{iαf}^{_{n,m}}, α=2π/1024. Then, many known methods of color image processing may be applied for processing color image components in quantum computers, followed by measurement of each color image superposition.

However, the concept of the quantum superposition allows for uniting the color components without additional qubits and embodiments involving new models of quantum representation, where color components of the image are processed and measured in one model. Embodiments may include two such models and may include the 3-point discrete Fourier transform of the qubits.

Embodiment with 3-Point DFT) for RGB Color Images

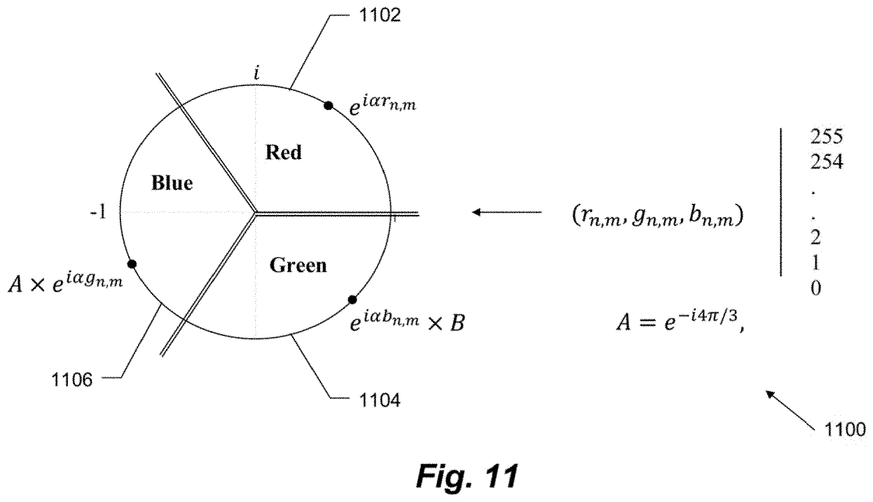

The primary colors may be united in quantum space by applying the concept of the 3-point DFT of qubits. For that, a color image f_{n,m}=(r_{n,m}, g_{n,m}, b_{n,m}) may be represented in the RGB model as a multi-qubit state in the following way. Because of three primary colors, the unit circle may be divided into three parts, each of 120°, and each color is a map to one circular arc. This transformation 1100 of colors (for the RGB model) is shown in FIG. 11. The range of each color component is considered to be in the integer interval [0,255].

Thus, to the red 1102, green 1104, and blue 1106 colors, three separate places are highlighted on the circle. Each pixel is defined with three points on the unit circle, and each point is in its color circular arc. For a grayscale image, each such triplet of points composes an equilateral triangle.

The red component of the color image can be represented as follows:

$$\begin{matrix}\vert {r}^{⋁} 〉 = \frac{1}{\sqrt{N M}} {\sum }_{m = 0}^{M - 1} {\sum }_{n = 0}^{N - 1} T [ {r}_{n , m} ] \vert n , m 〉 \\ = \frac{1}{\sqrt{N M}} {\sum }_{m = 0}^{M - 1} {\sum }_{n = 0}^{N - 1} {e}^{i α {r}_{n , m}} \vert n , m 〉 ,\end{matrix} \qquad ( 46 )$$

where α=2π/(3×256), and the transform is defined as T[r_{n,m}]=e^{iαr}^{_{n,m}}. The green and blue components of the color image can be map similarly to the other two circular arcs of 120 degrees each,

$$\begin{matrix}\begin{matrix}\vert {g}^{⋁} 〉 = {e}^{- i 2 π / 3} \frac{1}{\sqrt{N M}} {\sum }_{m = 0}^{M - 1} {\sum }_{n = 0}^{N - 1} T [ {g}_{n , m} ] \vert n , m 〉 \\ = \frac{1}{\sqrt{N M}} {e}^{- i 2 π / 3} {\sum }_{m = 0}^{M - 1} {\sum }_{n = 0}^{N - 1} {e}^{i α {g}_{n , m}} \vert n , m 〉 ,\end{matrix} & ( 47 ) \\ \begin{matrix}\vert {b}^{⋁} 〉 = {e}^{- i 4 π / 3} \frac{1}{\sqrt{N M}} {\sum }_{m = 0}^{M - 1} {\sum }_{n = 0}^{N - 1} T [ {b}_{n , m} ] \vert n , m 〉 \\ = \frac{1}{\sqrt{N M}} {e}^{- i 4 π / 3} {\sum }_{m = 0}^{M - 1} {\sum }_{n = 0}^{N - 1} {e}^{i α {b}_{n , m}} \vert n , m 〉 .\end{matrix} & ( 48 )\end{matrix}$$

These states may be united into the following superposition of states of colors:

$$\vert {( r , )}_{1} 〉 = \frac{1}{A} {\sum }_{m = 0}^{M - 1} {\sum }_{n = 0}^{N - 1} ( T [ {r}_{n , m} ] + T [ {g}_{n , m} ] {e}^{- i 2 π / 3} + T [ {b}_{n , m} ] {e}^{- i 4 π / 3} ) \vert n , m 〉 , \qquad ( 49 )$$

where A is the normalization coefficient and calculated by

$$A = \sqrt{{\sum }_{m = 0}^{M - 1} {\sum }_{n = 0}^{N - 1} {\vert [ {r}_{n , m} ] + T [ {g}_{n , m} ] {e}^{- i 2 π / 3} + T [ {b}_{n , m} ] {e}^{- i 4 π / 3} \vert}^{2}} .$$

This color superposition can also be written as

$$\vert {( r , )}_{1} 〉 = \frac{1}{{B}_{1}} ( \vert {r}^{⋁} 〉 + \vert {g}^{⋁} 〉 + \vert {b}^{⋁} 〉 ) , \qquad ( 50 )$$

where B₁=A/\sqrt{NM}. This quantum superposition is the sum of three color superpositions.

Up to A coefficient, the amplitude of the state |n, m [symbol] , which is denoted by

$${F}_{1} ( n , m ) = ( T [ {r}_{n , m} ] + T [ {g}_{n , m} ] {e}^{- \frac{i 2 π}{3}} + T [ {b}_{n , m} ] {e}^{- \frac{i 4 π}{3}} ) , \qquad ( 51 )$$

is the component of the 3-point discrete Fourier transform (DFT) of the signal

f₁=(T[r_{n,m}],T[gₘₘ],T[b_{n,m}])=(e^{iαr}^{_{n,m}},e^{iαg}^{_{n,m}},e^{iαb}^{_{n,m}}). (52)

The quantum superposition of colors

$$\vert {( r , )}_{1} 〉 = \frac{1}{{B}_{1}} {\sum }_{m = 0}^{M - 1} {\sum }_{n = 0}^{N - 1} {F}_{1} ( n , m ) \vert n , m 〉 \qquad ( 53 )$$

requires (r+s) qubits.

To restore the transforms T[r_{n,m}], T[g_{n,m}], and T[b_{n,m}] if the pixel-state |n, m [symbol] is measured, the completed 3-point DFT is needed. In other words, together with the component in Eq. (51), two more components are required,

$${F}_{0} ( n , m ) = ( T [ {r}_{n , m} ] + T [ {g}_{n , m} ] + T [ {b}_{n , m} ] )$$

$$and$$

$${F}_{2} ( n , m ) = ( T [ {r}_{n , m} ] + T [ {g}_{n , m} ] {e}^{- \frac{i 4 π}{3}} + T [ {b}_{n , m} ] {e}^{- \frac{i 2 π}{3}} ) .$$

The corresponding two additional (r+s)-quantum states are

$$\vert {( r , )}_{k} 〉 = \frac{1}{{A}_{k}} {\sum }_{m = 0}^{M - 1} {\sum }_{n = 0}^{N - 1} {F}_{k} ( n , m ) \vert n , m 〉 , k = 0 , 2 ,$$

where the coefficients

$${A}_{k} = \sqrt{{\sum }_{m = 0}^{M - 1} {\sum }_{n = 0}^{N - 1} {\vert T [ {r}_{n , m} ] + T [ {g}_{n , m} ] {e}^{- i 2 π k / 3} + T [ {b}_{n , m} ] {e}^{- i 4 π k / 3} \vert}^{2}} .$$

Thus, the qubit superposition may be defined as

$$\vert {( r , )}_{k} 〉 = \frac{1}{{B}_{k}} ( \vert {r}^{⋁} 〉 + {e}^{- i 2 π k / 3} \vert {g}^{⋁} 〉 + {e}^{- i 4 π k / 3} \vert {b}^{⋁} 〉 ) , k = 0 , 1 , 2 \qquad ( 54 )$$

where Bₖ=Aₖ/\sqrt{NM}, and call it the 3-point DFT of qubits of colors. It not difficult to see that

$$\frac{1}{3} {\sum }_{k = 0}^{2} {B}_{k}^{2} = \frac{1}{N M} {\sum }_{m = 0}^{M - 1} {\sum }_{n = 0}^{N - 1} ( {r}_{n , m}^{2} + {g}_{n , m}^{2} + {b}_{n , m}^{2} ) .$$

Embodiment with 3-Point DFT for RGB Color Images

Consider a model that is similar to model of the embodiment described above, but with amplitudes of color components at pixel-states instead of phases. For that, define another concept of the 3-point DFT of qubits for color images in the RGB model.

When applying the approach given in Eq. (49) to the normalized values of color components, that is, when using the concept of the qubit pixel for each color, the following superposition state may be considered:

$$\vert ( b 〉 = \frac{1}{A} ( \vert {r}^{⋁} 〉 + {e}^{- i 2 π / 3} \vert {g}^{⋁} 〉 + {e}^{- i 4 π / 3} \vert {b}^{⋁} 〉 ) , \qquad ( 55 )$$

where the quantum color state superpositions are

$$\vert {r}^{⋁} 〉 = \frac{1}{{E}_{r}} {\sum }_{m = 0}^{M - 1} {\sum }_{n = 0}^{N - 1} {r}_{n , m} \vert n , m 〉 , \vert {g}^{⋁} 〉 = \frac{1}{{E}_{g}} {\sum }_{m = 0}^{M - 1} {\sum }_{n = 0}^{N - 1} {g}_{n , m} \vert n , m 〉 , \\ \vert {b}^{⋁} 〉 = \frac{1}{{E}_{b}} {\sum }_{m = 0}^{M - 1} {\sum }_{n = 0}^{N - 1} {b}_{n , m} \vert n , m 〉 .$$

Here, the normalization coefficients Eᵣ, E_{g}, and E_{b} are the square roots of energies of the colors,

$${E}_{k} = \sqrt{{\sum }_{m = 0}^{M - 1} {{\sum }_{n = 0}}^{N - 1} {k}_{n , m}^{2}} , k = r , g , b .$$

The normalized coefficient A is calculated by

$$A = \sqrt{{\sum }_{m = 0}^{M - 1} {\sum }_{n = 0}^{N - 1} {\vert \frac{{r}_{n , m}}{{E}_{r}} + \frac{{g}_{n , m}}{{E}_{g}} {e}^{- i 2 π / 3} + \frac{{b}_{n , m}}{{E}_{b}} {e}^{- i 4 π / 3} \vert}^{2}} .$$

Thus, consider the superposition

$$\vert ( b 〉 = \frac{1}{A} {\sum }_{m = 0}^{M - 1} {\sum }_{n = 0}^{N - 1} ( \frac{{r}_{n , m}}{{E}_{r}} + \frac{{g}_{n , m}}{{E}_{g}} {e}^{- i 2 π / 3} + \frac{{b}_{n , m}}{{E}_{b}} {e}^{- i 4 π / 3} ) \vert n , m 〉 . \qquad ( 56 )$$

For simplicity of calculations, assume that all three color components of the image have the same energy, i.e., Eᵣ=E_{g}=E_{b}=E. Then, the superposition in Eq. (56) can be written as

$$\vert ( b 〉 = \frac{1}{K} {\sum }_{m = 0}^{M - 1} {\sum }_{n = 0}^{N - 1} ( {r}_{n , m} + {g}_{n , m} {e}^{- i 2 π / 3} + {b}_{n , m} {e}^{- i 4 π / 3} ) \vert n , m 〉 \qquad ( 57 )$$

and the coefficient K is

$$K = AE = \sqrt{{\sum }_{m = 0}^{M - 1} {\sum }_{n = 0}^{N - 1} {\vert {r}_{n , m} + {g}_{n , m} {e}^{- i 2 π / 3} + {b}_{n , m} {e}^{- i 4 π / 3} \vert}^{2}} = \sqrt{{\sum }_{m = 0}^{M - 1} {\sum }_{n = 0}^{N - 1} {\vert {F}_{1} ( n , m ) \vert}^{2}} .$$

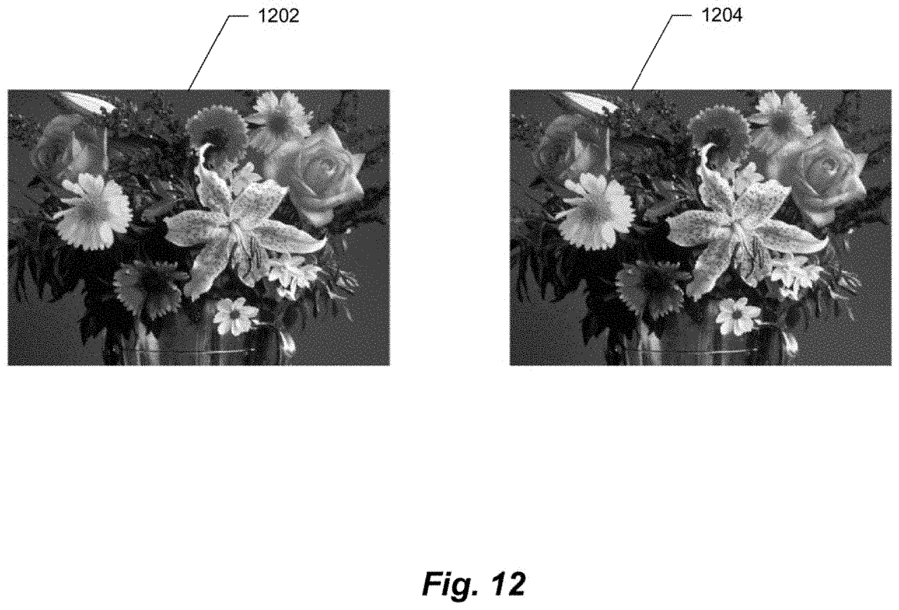

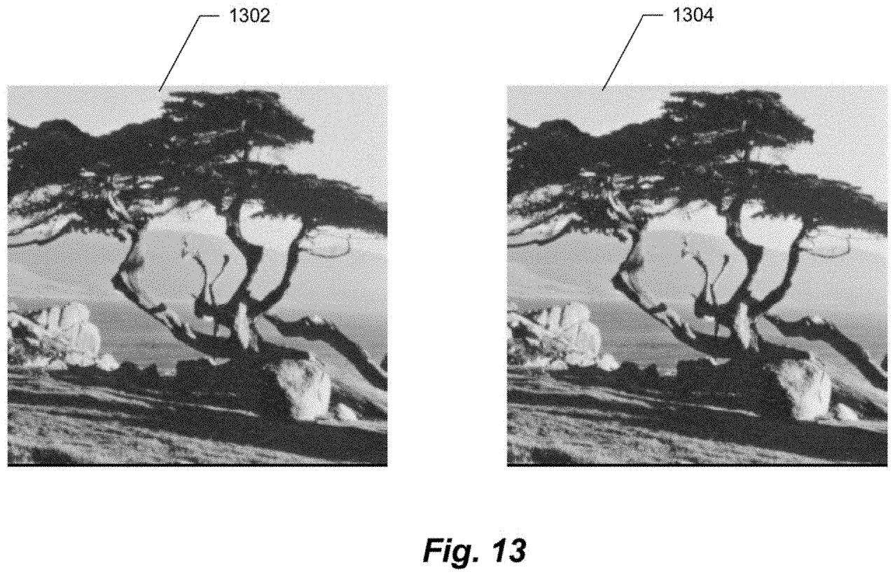

If the energies of the image color components are different, these components can be linearly amplified, in order to equalize their energies, and then represented by Eq. (57). This method may be called the color energy equalization of the image. As an example, FIG. 12 shows an original image 1202 and the image after energy equalization 1204. Similarly, FIG. 13 shows an original image 1302 and the image after energy equalization 1304. The energies of colors were equated to the average energy of colors. One can note that the equalized image has good quality as the original image. Moreover, the original image maybe be reconstructed from the equalized one, by using the ratios of energies Eₖ, k=r, b, g.

At each quantum pixel |n, m [symbol] , the amplitude is the above superposition Eq, (57), which is the component of the 3-point DFT, up to the constant 1/K, which is

$${F}_{1} = {F}_{1} ( n , m ) = ( {r}_{n , m} + {g}_{n , m} {e}^{- i 2 π / 3} + {b}_{n , m} {e}^{- i 4 π / 3} ) .$$

The data are real, and for the 3-point DFT, the 2nd component

$${F}_{2} = {\overline{F}}_{1} = ( {r}_{n , m} + {g}_{n , m} {e}^{i 2 π / 3} + {b}_{n , m} {e}^{i 4 π / 3} ) .$$

Thus, the component F₁ together with the gray value v_{n,m}=(r_{n,m}+g_{n,m}+b_{n,m})/3 determines the completed 3-point DFT of the colors,

f_{n,m}=(r_{n,m},g_{n,m},b_{n,m})→(F₀=3v_{n,m},F₁,F₂).

The inverse 3-point DFT results in the original colors, (F₀, F₁, F₂)→(r_{n,m}, g_{n,m}, b_{n,m}). Thus, define the color image (r+s)-state quantum representation (51), which also can be written as

$$\vert \vert b 〉 = \frac{1}{A} ( \vert {r}^{⋁} 〉 + \vert {g}^{⋁} 〉 {e}^{- i2 π / 3} + \vert {b}^{⋁} 〉 {e}^{- i 4 π / 3} ) .$$

This representation can be considered as the 3-point DFT of the color-qubit state

|Čₚ [symbol] =(|ř [symbol] +|\check{g} [symbol] e^{-i2πp/3}+|b [symbol] e^{-i4πp/3}), p=0,1,2. (58)

This is the 3-point DFT of the color state superposition, and it requires (r+s) qubits for each p=0, 1, and 2. This model differs from the model of image representation that is described by Eqs. (26) and (27) when the information of colors is written in polar form for amplitudes of the states.

It is to be noted that information on the image in each pixel is written in the phase-type amplitude. There is no constraint on the size and range of the signal and image when using the FTQR.

FTQR possesses properties, such as the sum, amplification, shifting, that are not available for known methods of signal and image quantum representation.

The calculation of phase-type amplitudes in signal and image representation is simple. These amplitudes can be calculated in advance and used by the lookup table method.

In FTQR, all states in the superposition have an equal probability.

FTQR requires the minimum number of qubits for signals and images.

FTQR is an effective tool to process quantum signals and images in the frequency domain.

FTQR has a simple algorithm for signal and image reconstruction after measuring the superposition state. When measuring |\check{f} [symbol] in (45) and getting the state |n, m [symbol] , it's amplitude e^{iαf}^{_{n,m}}/\sqrt{NM} allows for calculating the value f_{n,m} of the image.

FTQR is not the classical discrete Fourier transform (DFT). The inverse DFT requires knowledge of all components of the transform. For FTQR, the image reconstruction from this representation relates to the measurement of the superposition state, as stated above.

The concept of the 3-point DFT on qubits in the above 3^{rd} model allows processing colors as units in the frequency domain.

Quaternion Quantum Image Representation

Quaternion Numbers and Qubits

In quaternions, the imaginary part of the number is extended to three dimensions, that is, it has three component imaginary parts Error! Reference source not found.. A quaternion is a number that is represented in the following form:

q=a+(bi+cj+dk)=a+bi+cj+dk. (59)

Here, the coefficients a, b, c, and d are real numbers. The imaginary units i, j, and k are defined with the following multiplication laws:

ij=−ji=k, jk=−kj=i, ki=−ik=−j, i²=j²=k²=ijk=−1.

The quaternion number q can be referred to as a vector q=(a, b, c, d) in the 4-D real space R⁴. The number a is referred to as the “real” part of q and (bi+cj+dk) is the “imaginary” part of q. The quaternion conjugate of q equals q̅=a−bi−cj−dk and the modulus |q|=qq̅=\sqrt{a²+b²+c²+d²}.

The qubit is described by the superposition of two basic states

|ψ₁ [symbol] =a₀|0 [symbol] +a₁| [symbol] (60)

with real or complex amplitudes a₀ and a₁ satisfying the condition |a₀²+|a₁²=1. We also consider the concept of two qubits which is a superposition of four basic states

|ψ₂ [symbol] =a₀|00 [symbol] +a₁|01 [symbol] +a₂|10 [symbol] +a₃|11) (61)

with amplitudes a₀, a₁, a₂, and a₃ that satisfy the condition |a₀|²+|a₁|²+|a₂|²+|a₃|²=1.

The question is why the amplitudes of states are considered only real and complex numbers. Assume that such amplitudes are taken from other arithmetic, for example, quaternion numbers. In this case, the 2-qubit in (3) can be considered with quaternion amplitudes as

|ψ₂ [symbol] =q₀|00 [symbol] +q₁|01 [symbol] +q₂|10 [symbol] +g₃|11 [symbol] . (62)

Here, the quaternion coefficients q₀, q₁, q₂, and q₃ satisfy the condition |q₀|²+|q₁|²+|q₂|²+|q₃|²=1. We consider a subspace of such 2-qubits when the amplitudes of their states are the following type numbers: q₀ is real, and q₁, q₂, and q₃ are the numbers measured along the imaginary units i, j, and k, respectively? We call such 2-qubits the quaternion 2-qubits.

Quaternion and Color Image Representation

Embodiments may provide a representation of a color image in quaternion space, followed by a representation of the states of qubits. If the color image is given in the RGB format, three primary color components, R (Red), G (Green), and B (Blue) of a pixel, can be transferred to three imaginary parts of quaternion numbers with dimensions i, j, and k. Thus, the color image f_{n,m} can be transformed into the imaginary part of the pure quaternion data as

f_{n,m}=0+(r_{n,m}i+g_{n,m}j+b_{n,m}k) (63)

In many methods of color imaging, for instance, the a-rooting by the quaternion 2-D discrete Fourier transform (QDFT) Error! Reference source not found.Error! Reference source not found., the gray component is processed together with the colors as one unit, when considering the real part of the quaternion image equal

a_{n,m}=(r_{n,m}+g_{n,m}+b_{n,m})/3. (64)

This component can also be calculated as the image brightness,

a_{n,m}=0.30r_{n,m}+0.59g_{n,m}+0.11b_{n,m}. (65)

In general, such quaternion numbers can be represented as the sums of “complex numbers” from three different complex planes,

f_{n,m}=(γ_{n,m}+ir_{n,m})+(λ_{n,m}+jg_{n,m})+(χ_{n,m}+kb_{n,m}), (66)

where the coefficients γ_{n,m}, λ_{n,m}, and χ_{n,m} are real positive numbers. In this representation, the quaternion image with real part from (64) or (65) can be referred to the case γ_{n,m}+λ_{n,m}+χ_{n,m}=1, when γ_{n,m}=λ_{n,m}=χ_{n,m}=⅓. The case γ_{n,m}=λ_{n,m}=χ_{n,m}=0 corresponds to the pure quaternion image in (63).

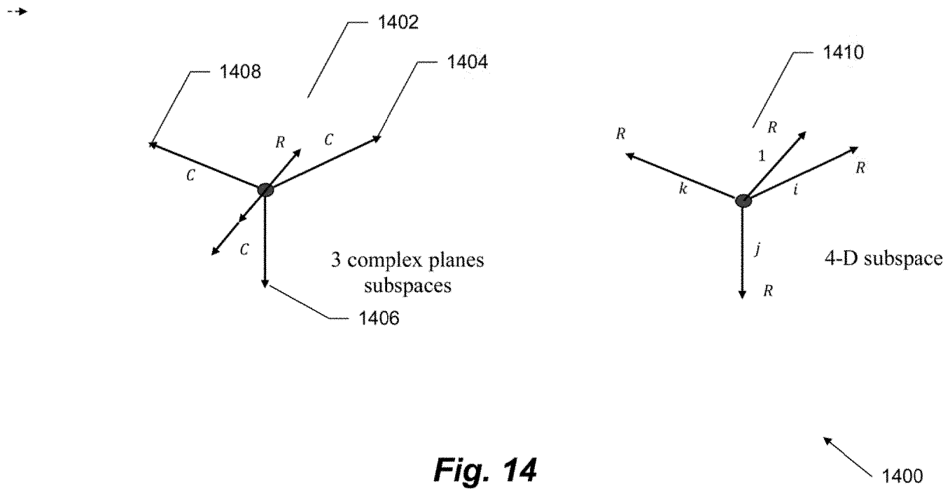

Transformation 1400 from three complex subspaces is shown in FIG. 14. The threefold complex plane 1402, where each plane is colored by red 1404, green 1406, and blue 1408 as the primary colors in the RGB model Error! Reference source not found.. These planes connected along the real line R. For the 4-D subspace of quaternion numbers 1410 for the model of color images with nonzero grayscale components, it may be considered that all components of quaternion images are not negative numbers.

The quaternion image representing the color image f_{n,m}={r_{n,m}, g_{n,m}, b_{n,m}} with the grayscale component

q_{n,m}=a_{n,m}+(r_{n,m}i+g_{n,m}j+b_{n,m}k) (67)

can be written in each pixel (n, m) in the normalized form

$${q}_{n , m} = {\tilde{a}}_{n , m} + ( {\tilde{r}}_{n , m} i + {\tilde{g}}_{n , m} j + {\tilde{b}}_{n , m} k ) = \frac{1}{A} [ {a}_{n , m} + ( {r}_{n , m} i + {g}_{n , m} j + {b}_{n , m} k ) ] . \qquad ( 68 )$$

Here, the constant is

A=|q_{n,m}|=\sqrt{a_{n,m}²+r_{n,m}²+g_{n,m}²+b_{n,m}²}.

For the pixel (n, m), the following 2-qubit state can be considered:

|q_{n,m} [symbol] =ã_{n,m}|00 [symbol] +i\tilde{r}_{n,m}|01 [symbol] +jg_{n,m}|10 [symbol] +kb_{n,m}|11 [symbol] . (69)

The imaginary units i, j, and k are used in this representation; this fact is specific for quaternion images. The quaternion imaging is an effective tool in processing color images, especially in the frequency domain, by using the concept of the quaternion discrete Fourier transform Error! Reference source not found.. The multiplication in quantum arithmetic is not a commutative operation. Therefore, the superposition in (11) and the following one

ã_{n,m}|00 [symbol] +\tilde{r}_{n,m}|01 [symbol] +\tilde{g}_{n,m}|10 [symbol] +\tilde{b}_{n,m}|11

[symbol]

are different in calculations. The measurement of states i|01 [symbol] and |01 [symbol] will be accomplished with the same probability |\tilde{r}_{n,m}|² in both superpositions. The same is true for the state j|10 [symbol] and |10 [symbol] , and k|11 [symbol] and |11 [symbol] . Introducing the “imaginary unit states” i|01 [symbol] , j|10 [symbol] , and k|11 [symbol] , the superposition in Eq. 69 as may be written as

|q_{n,m} [symbol] ã_{n,m}|00 [symbol] +\tilde{r}_{n,m}i|01 [symbol] g_{n,m}j|10 [symbol] +\tilde{b}_{n,m}k|11 [symbol] . (70)

This may be called the quaternion 2-qubit state at the pixel (n, m).

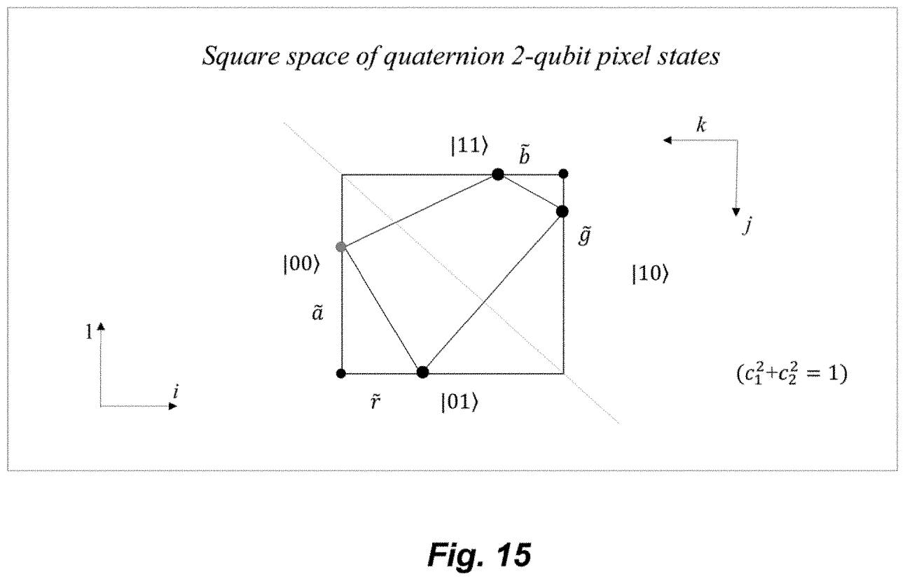

The Bloch sphere is used to illustrate the qubits Error! Reference source not found. and in quaternion space the equation |q_{n,m}|²=1 describes the points in the 4-D unit sphere Error! Reference source not found.. The quaternion 2-qubit state at a single pixel may be illustrated by four points on the perimeter of the unit square, which are measured on its sides by values ã=ã_{n,m}, \tilde{r}=\tilde{r}_{n,m}, \tilde{g}=\tilde{g}_{n,m}, and \tilde{b}=\tilde{b}_{n,m}, as shown in FIG. 15. The obtained quadrangle defines a 2-qubit state that represents the pixel of the quaternion image qₙₘ. Such a quadrangle turns into a point when one of its points is on top of a square, for instance, when ã_{n,m}=1.

In an embodiment, for the entire image of size N×M pixels, where N=2^{r}, M=2^{s}, r,s>1, the quantum superposition state with NM pairs of qubits can be defined as follows:

$$\vert {f}^{⋁} 〉 = \frac{1}{\sqrt{NM}} {\sum }_{m = 0}^{M - 1} {\sum }_{n = 0}^{N - 1} \vert {q}_{n , m} 〉 ⊗ \vert n , m 〉 . \qquad ( 71 )$$

Here, the operation ⊗ denotes the tensor product. For integers n=0, 1, . . . , N−1 and m=0, 1, . . . , M−1, the states |n [symbol] and |m [symbol] are the quantum computational basis states which are written in their binary forms, and

|n,m [symbol] =|n [symbol] ⊗|m [symbol] =|nᵣ₋₁nᵣ₋₂ . . . n₁n₀ [symbol] ⊗|mₛ₋₁mₛ₋₂ . . . m₁m₀ [symbol] . (72)

In the representation of Eq. 71, two qubits of the quaternion state are added to (r+s) qubits that are describing the pixel number. Thus, a total 2+(r+s) qubits are required. It seems that the quantum 2-qubit state |q_{n,m} [symbol] is prepared in Eq. 70 for each pixel (n, m), the number of which is NM. In Eq. 71, the quaternion 2-qubit states are all nested in the superposition with the pixel number-states |n, m [symbol] . This is why the total number of required qubits equals 2+(r+s), not NM.

When measuring the quaternion 2-qubit in (70), the state 101) might be received with probability (\tilde{r}_{n,m})², and similarly for the other three basic states. To recover the original red color, we need to use the number |q_{n,m}|,

r_{n,m}=|q_{n,m}|\tilde{r}_{n,m}.

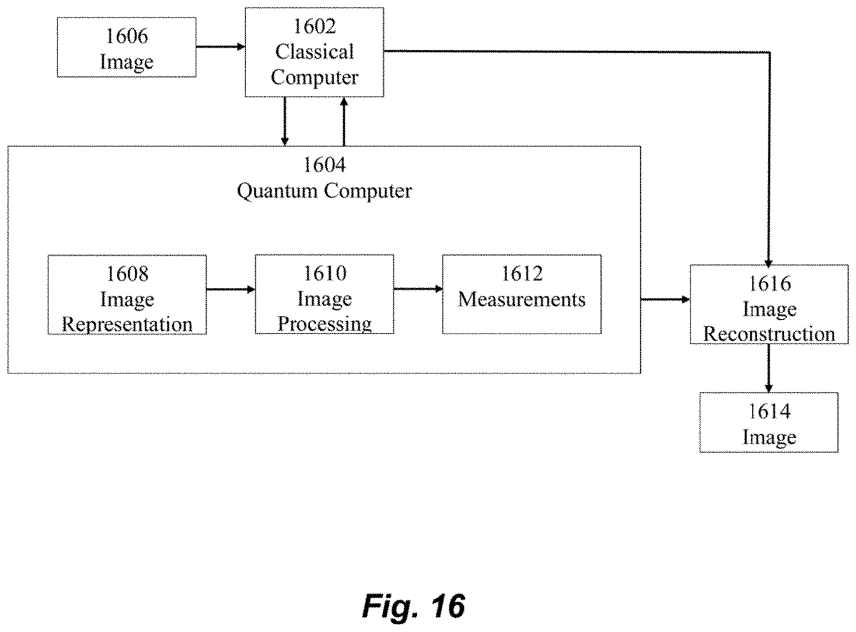

The superposition |\check{f} [symbol] in (64) does not carry such information, |q_{n,m}|. However, it is assumed that this information is available. Indeed, to build the superposition in (71) with (r+s+2) qubits, the image should be copied from a classical computer, where the image is saved. Thus, the required information can be calculated and saved in the classical computer. In other words, quantum computing may be performed under interconnection with the classical computer, as shown in FIG. 16.

An example of a combined classical/quantum computing system 1600 is shown in FIG. 16. In this example, a classical computer 1602 may be interconnected with a quantum computer 1604. In order to process an image 1606, image 1606 may be input to classical computer 1602 and processed, as described above, for input to quantum computer 1604. Quantum computer 1604 may perform processing starting with generating a quantum representation 1608 of image 1606. Representation 1608 may be processed by image processing 1610 and the results of the image processing may be obtained by measurements 1612. Measurements 1612 may be input to classical computer 1602 and an output image 1614 may be reconstructed 1616, as described above.

It should be noted that the data of NM values of |q_{n,m}| can be saved in a quantum computer by using a small number of qubits. Indeed, the following (r+s)-qubit state can be considered:

$$\vert {q}^{⋁} 〉 = \frac{1}{A} {\sum }_{m = 0}^{M - 1} {\sum }_{n = 0}^{N - 1} \vert {q}_{n , m} \vert ⊗ \vert n , m 〉 , \qquad ( 73 )$$

where the number A is calculated by

$$A = \sqrt{{\sum }_{m = 0}^{M - 1} {\sum }_{n = 0}^{N - 1} {\vert {q}_{n , m} \vert}^{2}} .$$

For comparison, we consider one of the known models of image representation with the concept of quantum pixel Error! Reference source not found.Error! Reference source not found. (described in Section 2.2.1). For instance, in the qubit lattice model (QLM), the grayscale or color image f=f_{n,m} of size N×M is presented by the following quantum state (see Eq. 26):

$$\vert {f}^{⋁} 〉 = \frac{1}{\sqrt{NM}} {\sum }_{m = 0}^{M - 1} {\sum }_{n = 0}^{N - 1} ( cos {n , m}_{} \vert 0 〉 + {e}^{i γ} sin {n , m}_{} \vert 1 〉 ) ⊗ \vert n , m 〉 . \qquad ( 74 )$$

A pixel (n, m), the values of gray or color are encoded in the angle ϑ_{n,m}, and γ is a constant. This representation requires (r+s+1) qubits for the color image and the same number of qubits for the grayscale image. Thus, total 2(r+s+1) qubits are required when processing the grayscale plus the color image; they are processed separately. In the proposed model with quaternion 2-qubit states, the grayscale and color components of the image are processed together as one unit. The required memory is (r+s+2) qubits.

An embodiment may provide the following representation of the quaternion image in quantum computing. It is known that a quaternion number q=a+q′ can be written in polar form as q=|q|e^{μϑ} Error! Reference source not found., where a pure unit quaternion is μ=q′/|q| and the angle is calculated by ϑ=cos⁻¹(a/|q|). Here, a denotes the real part of the quaternion q, and q′ is the imaginary part of q, and a²+|q′|²=|q|². Indeed, the following calculations hold:

$$q = a + {q}^{′} = \vert q \vert ( \frac{a}{\vert q \vert} + \frac{{q}^{′}}{\vert {q}^{′} \vert} \frac{\vert {q}^{′} \vert}{\vert q \vert} ) = \vert q \vert ( \frac{a}{\vert q \vert} + μ \frac{\vert {q}^{′} \vert}{\vert q \vert} ) = \vert q \vert ( cos + μsin )$$

and the quaternion exponential function is defined as e^{μϑ}=cos ϑ+μ sin ϑ.

Thus, at each pixel (n, m), the quaternion number can be written as

$${q}_{n , m} = {a}_{n , m} + {q}_{n , m}^{′} = {a}_{n , m} + ( {r}_{n , m} i + {g}_{n , m} j + {b}_{n , m} k ) = \vert {q}_{n , m} \vert \qquad ( 75 )$$

where

$$\begin{matrix}μ = {μ}_{n , m} = \frac{{q}_{n , m}^{′}}{\vert {q}_{n , m}^{′} \vert} = \frac{{r}_{n , m} i + {g}_{n , m} j + {b}_{n , m} k}{\sqrt{{r}_{n , m}^{2} + {g}_{n , m}^{2} + {b}_{n , m}^{2}}} & ( 76 ) \\ and & \\ = {n , m}_{} = {cos}^{- 1} ( \frac{{a}_{n , m}}{\sqrt{{a}_{n , m}^{2} + {r}_{n , m}^{2} + {g}_{n , m}^{2} + {b}_{n , m}^{2}}} ) . & ( 77 )\end{matrix}$$

Considering the qubit superposition |q|(cos ϑ|0 [symbol] +μ sin ϑ|1 [symbol] ) at the pixel, the quaternion image can be represented by (r+s+1) qubits,

$$\vert {f}^{⋁} 〉 = \frac{1}{\sqrt{NM}} {\sum }_{m = 0}^{M - 1} {\sum }_{n = 0}^{N - 1} ( cos {n , m}_{} \vert 0 〉 + μsin {n , m}_{} \vert 1 〉 ) ⊗ \vert n , m 〉 . \qquad ( 78 )$$

Analyzing the model of quantum imaging shown in FIG. 16, one can see that in each pixel, the measurement of the pixel qubit allows for calculating the amplitudes of the basic states |0 [symbol] and |1 [symbol] from the cosine and μ×sine, by the following algorithm.

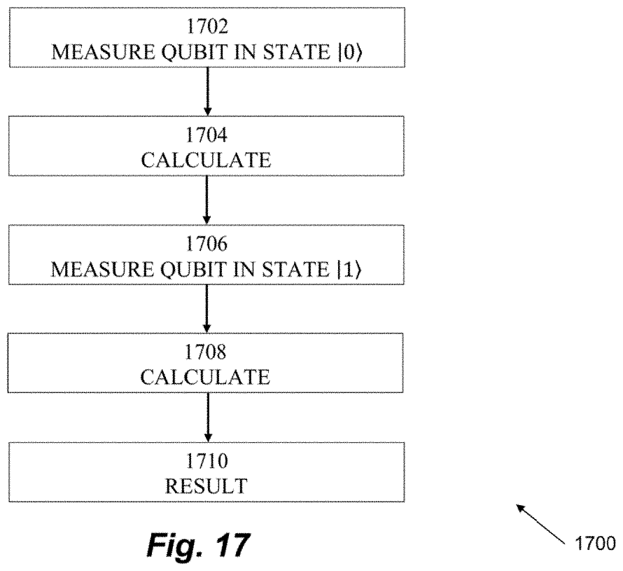

An exemplary process 1700 of quaternion (or color) image reconstruction, which may be performed in the system shown in FIG. 16, is shown in FIG. 17. In this example, process 1700 begins with 1702, in which a Qubit in state |0 [symbol] and amplitude cos ϑ_{n,m} is measured. At 1704, the process calculates

a=a_{n,m}=|q|cos ϑn,m, where q=q_{n,m}. a.

|q′|²=|q|²−a²; b.

At 1706, a Qubit in state |1 [symbol] and amplitude μ sin ϑ_{n,m} is measured. At 1708, the process calculates

μ=(μ sin ϑ_{n,m})/sin ϑ_{n,m}, a.

q′=μ|q′|, b.

three imaginary components of q′=r_{n,m}i+g_{n,m}j+b_{n,m}k. c.

At 1710, the result is colors and

It is assumed that the data of |q_{n,m}| is available in the classical computer, or it has been presented as (r+s)-qubit state |\check{q} [symbol] in (51).

In an embodiment, a model of a color image may be represented by (r+s+1) qubits in quantum computing, as described above. The color image may be represented by the following (r+s+1)-qubit state:

$$\vert {f}^{⋁} 〉 = \frac{1}{\sqrt{NM}} {\sum }_{n = 0}^{N - 1} {\sum }_{m = 0}^{M - 1} ( {z}_{n , m ; 0} \vert 0 〉 + {z}_{n , m ; 1} \vert 1 〉 ) ⊗ \vert n , m 〉 . \qquad ( 79 )$$

This model, consider for comparison with the following general model for quaternion images. It should be noted that the quaternion numbers may be written as a coupled complex number

q=a+ib+jc+kd=(a+jc)+i(b+jd)

Each of these complex numbers can be written in the polar form Error! Reference source not found.,

(a+jc)=z₀e^{jφ}^{₁}, (b+jd)=z₁e^{jφ}^{₂},

where z₁ and z₂ are positive real numbers. Therefore, the value q=q_{n,m} of the image at pixel (n, m) can be written in form of single-qubit as

$$\vert q 〉 = \frac{{z}_{0} {e}^{j {ϕ}_{1}} \vert 0 〉 + {z}_{1} {e}^{j {ϕ}_{2}} \vert 1 〉}{\vert q \vert} .$$

Here, |z₀|²=|z₁²=|q|². The quaternion image thus can be presented by the following (r+s+1)-qubit state:

$$\vert {f}^{⋁} 〉 = \frac{1}{\sqrt{NM}} {\sum }_{n = 0}^{N - 1} {\sum }_{m = 0}^{M - 1} ( \frac{{z}_{n , m ; 0} {e}^{j {ϕ}_{1}} \vert 0 〉 + {z}_{n , m ; 1} {e}^{j {ϕ}_{2}} \vert 1 〉}{\vert {q}_{n , m} \vert} ) ⊗ \vert n , m 〉 . \qquad ( 80 )$$

With the superposition state |\check{q} [symbol] in (73), the quaternion image requires (r+s+1) qubits.

It is to be noted that the concept of quaternion images may include the four grayscale images, which means that four images can be processed as one. Therefore, the representations of quaternion images that were described above can be used to represent and process four images in qubits. Moreover, in quaternion algebra, the grayscale image of size N×M pixels can be processed as one quaternion image of size N/2×M/2 pixels. Such techniques were successfully applied in grayscale image enhancement by quaternion alpha-rooting method Error! Reference source not found.Error! Reference source not found..

The quantum representation of such a quaternion image requires [(r−1)+(s−1)+2] qubits, i.e., (r+s) qubits. This is the smallest number of qubits for grayscale image representation. The existent methods of grayscale image representation in quantum computing required no less than (r+s+1) qubits Error! Reference source not found.Error! Reference source not found.Error! Reference source not found.. Only for pixel states |n, m [symbol] , qubits in number (r+s) are required, and additional qubits are used in these methods for gray or color information in the pixel.

Embodiments may similarly apply to the above quaternion models new octonion-based image models to quantum computing, which will allow for effective processing simultaneously of two-color images, or up to eight grayscale images.

Embodiments may include a universal quantum computer with multi-level qudits, which unlike the qubit may have two, three, and more states. The concept of quaternion 2-qubit, i.e., 4-level concept, can be used in algorithms for computing in such quantum computers. Similar to the quaternion 2-qubit, we can introduce the octonion 3-qubit with 8 state levels for multi-signal representation and processing in such quantum computers.

Embodiments of the described quantum circuits for copying qubits and image representation may be used in the hardware and software needed to create working quantum computers and quantum simulators and in computing devices, such as prospective quantum processing devices for machine learning applications, including Artificial neural networks. A number of techniques exist or are being developed or investigated to implement such quantum computing. Embodiments may be implemented using any and all such techniques. For example, superconducting quantum computing, wherein qubits may be implemented by the state of small superconducting electronic circuits, such as Josephson junctions, have been implemented and are operational. Trapped ion quantum computers, wherein qubits may be implemented by the internal state of trapped ions, have been demonstrated. Other techniques being developed or investigated may include neutral atoms in optical lattices, wherein qubits may be implemented by internal states of neutral atoms trapped in an optical lattice, spin-based quantum dot computers, wherein qubits may be implemented by the spin states of trapped electrons, spatial-based quantum dot computers, wherein qubits may be implemented by electron position in double quantum dots, quantum computing using engineered quantum wells, coupled quantum wire, wherein qubits may be implemented by a pair of quantum wires coupled by a quantum point contact, Nuclear Magnetic Resonance Quantum Computers (NMRQC) implemented with the nuclear magnetic resonance of molecules in solution, wherein qubits may be implemented by nuclear spins within the dissolved molecule and probed with radio waves, solid-state NMR Kane quantum computers, wherein qubits may be implemented by the nuclear spin state of phosphorus donors in silicon, electrons-on-helium quantum computers, wherein qubits may be implemented by the electron spin, cavity quantum electrodynamics (CQED), wherein qubits may be implemented by the internal state of trapped atoms coupled to high-finesse cavities, molecular magnet, wherein qubits may be implemented by spin states, Fullerene-based ESR quantum computer, wherein qubits may be implemented based on the electronic spin of atoms or molecules encased in fullerenes, nonlinear optical quantum computers, wherein qubits may be implemented by processing states of different modes of light through both linear and nonlinear elements, linear optical quantum computers, wherein qubits may be implemented by processing states of different modes of light through linear elements, such as mirrors, beam splitters and phase shifters, diamond-based quantum computers, wherein qubits may be implemented by the electronic or nuclear spin of nitrogen-vacancy centers in diamond, Bose-Einstein condensate-based quantum computers, transistor-based quantum computers such as string quantum computers with entrainment of positive holes using an electrostatic trap, rare-earth-metal-ion-doped inorganic crystal based quantum computers, wherein qubits may be implemented by the internal electronic state of dopants in optical fibers, metallic-like carbon nanospheres based quantum computers, etc.

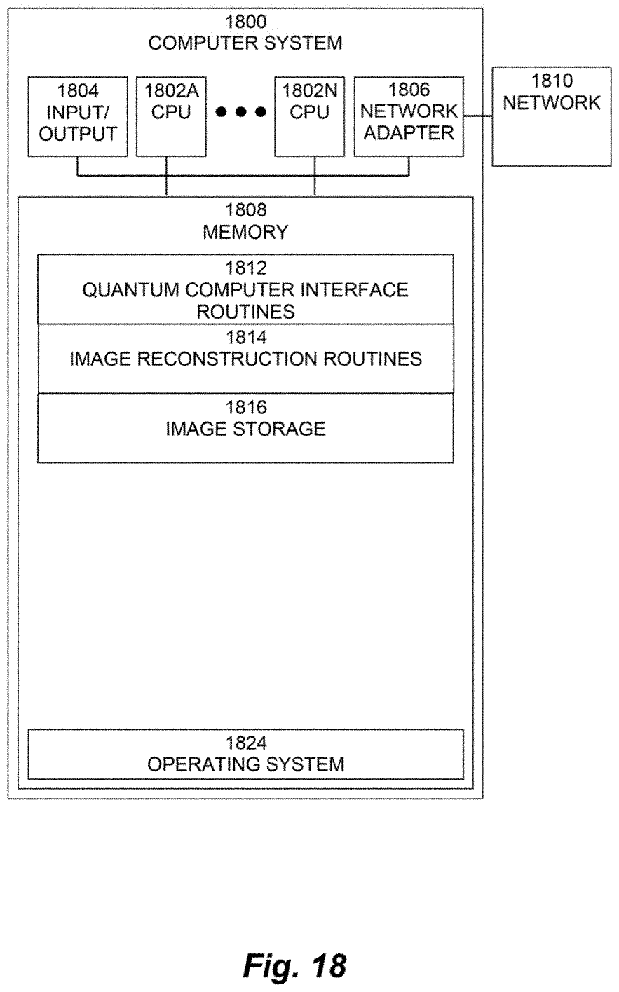

An exemplary block diagram of a classical computer system 1800, in which processes involved in the embodiments described herein may be implemented, is shown in FIG. 18. Computer system 1800 may be implemented using one or more programmed general-purpose computer systems, such as embedded processors, systems on a chip, personal computers, workstations, server systems, and minicomputers or mainframe computers, or in distributed, networked computing environments. Computer system 1800 may include one or more processors (CPUs) 1802A-1802N, input/output circuitry 1804, network adapter 1806, and memory 1808. CPUs 1802A-1802N execute program instructions in order to carry out the functions of the present communications systems and methods. Typically, CPUs 1802A-1802N are one or more microprocessors, such as an INTEL CORE® processor. FIG. 18 illustrates an embodiment in which computer system 1800 is implemented as a single multi-processor computer system, in which multiple processors 1802A-1802N share system resources, such as memory 1808, input/output circuitry 1804, and network adapter 1806. However, the present communications systems and methods also include embodiments in which computer system 1800 is implemented as a plurality of networked computer systems, which may be single-processor computer systems, multi-processor computer systems, or a mix thereof.

Input/output circuitry 1804 provides the capability to input data to, or output data from, computer system 1800. For example, input/output circuitry may include input devices, such as keyboards, mice, touchpads, trackballs, scanners, analog to digital converters, etc., output devices, such as video adapters, monitors, printers, etc., and input/output devices, such as, modems, etc. Network adapter 1806 interfaces device 1800 with a network 1810. Network 1810 may be any public or proprietary LAN or WAN, including, but not limited to the Internet.

Memory 1808 stores program instructions that are executed by, and data that are used and processed by, CPU 1802 to perform the functions of computer system 1800. Memory 1808 may include, for example, electronic memory devices, such as random-access memory (RAM), read-only memory (ROM), programmable read-only memory (PROM), electrically erasable programmable read-only memory (EEPROM), flash memory, etc., and electro-mechanical memory, such as magnetic disk drives, tape drives, optical disk drives, etc., which may use an integrated drive electronics (IDE) interface, or a variation or enhancement thereof, such as enhanced IDE (EIDE) or ultra-direct memory access (UDMA), or a small computer system interface (SCSI) based interface, or a variation or enhancement thereof, such as fast-SCSI, wide-SCSI, fast and wide-SCSI, etc., or Serial Advanced Technology Attachment (SATA), or a variation or enhancement thereof, or a fiber channel-arbitrated loop (FC-AL) interface.

The contents of memory 1808 may vary depending upon the function that computer system 1800 is programmed to perform. In the example shown in FIG. 18, exemplary memory contents are shown representing routines and data for embodiments of the processes described above. However, one of skill in the art would recognize that these routines, along with the memory contents related to those routines, may not be included on one system or device, but rather may be distributed among a plurality of systems or devices, based on well-known engineering considerations. The present systems and methods may include any and all such arrangements.

In the example shown in FIG. 18, memory 1808 may include model generation routines 1812, transition probability matrix estimation routines 1814, interpolation routines 1816, state transition generation routines 1818, recording routines 1820, learning routines 1822, and operating system 1824. Model generation routines 1812 may include software routines to generate an intermediate model, as described above. Transition probability matrix estimation routines 1814 may include software routines to generate a transition probability matrix and corresponding vector of costs, as described above. Interpolation routines 1816 may include software routines to interpolate historical data, as described above. State transition generation routines 1818 may include software routines to interpolate historical data, as described above. Recording routines 1820 may include software routines to record the current state, next state, action, and reward for the transition, as described above. Learning routines 1822 may include software routines to generate an intermediate model that approximately models the environment, and which has learned from the transition probability matrix, as described above. Operating system 1824 may provide overall system functionality.

As shown in FIG. 18, the present communications systems and methods may include implementation on a system or systems that provide multi-processor, multi-tasking, multi-process, and/or multi-thread computing, as well as implementation on systems that provide only single processor, single thread computing. Multi-processor computing involves performing computing using more than one processor. Multi-tasking computing involves performing computing using more than one operating system task. A task is an operating system concept that refers to the combination of a program being executed and bookkeeping information used by the operating system. Whenever a program is executed, the operating system creates a new task for it. The task is like an envelope for the program in that it identifies the program with a task number and attaches other bookkeeping information to it. Many operating systems, including Linux, UNIX®, OS/2®, and Windows®, are capable of running many tasks at the same time and are called multitasking operating systems. Multi-tasking is the ability of an operating system to execute more than one executable at the same time. Each executable is running in its own address space, meaning that the executables have no way to share any of their memory. This has advantages, because it is impossible for any program to damage the execution of any of the other programs running on the system. However, the programs have no way to exchange any information except through the operating system (or by reading files stored on the file system). Multi-process computing is similar to multi-tasking computing, as the terms task and process are often used interchangeably, although some operating systems make a distinction between the two.

The present invention may be a system, a method, and/or a computer program product at any possible technical detail level of integration. The computer program product may include a computer readable storage medium (or media) having computer readable program instructions thereon for causing a processor to carry out aspects of the present invention. The computer readable storage medium can be a tangible device that can retain and store instructions for use by an instruction execution device.

The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers, and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Although specific embodiments of the present invention have been described, it will be understood by those of skill in the art that there are other embodiments that are equivalent to the described embodiments. Accordingly, it is to be understood that the invention is not to be limited by the specific illustrated embodiments, but only by the scope of the appended claims.

What is claimed is:

1. A method for copying a qubit comprising:
receiving a qubit in a genetic state of linear superposition |ψ [symbol] =a|0 [symbol] +b|1 [symbol] ;
applying sequentially a plurality of CNOT operators to form a result comprising a 4-qubit output state having duplicated qubits in a plurality of qubits of the output state;
measuring the 4-qubit output state;
applying a 2-Controlled-NOT operator with a target qubit to the output of the second CNOT operator to output a plurality of qubits; and
measuring a qubit of the output plurality of qubits to obtain duplicated qubits |ψ² [symbol] .

2. The method of claim 1, wherein applying sequentially a plurality of CNOT operators comprises:
applying a first CNOT operator (gate X) with a control qubit |ψ [symbol] and controlling (target) state |0) to form a result comprising a 2-qubit state |φ [symbol] =a|00 [symbol] +b|11 [symbol] ;
applying a second CNOT operator with the control qubit |ψ [symbol] and a second input being |φ [symbol] ; wherein the target is a second qubit of |φ [symbol] , to form a result comprising a 4-qubit output state having duplicated qubits in the 2^{nd} and 3^{rd} qubits of the output state.

3. The method of claim 1, wherein applying a 2-Controlled-NOT operator comprises:
applying a 2-Controlled-NOT operator with a target qubit number of 3 to the output of the second CNOT operator to output a plurality of qubits

4. The method of claim 3, wherein measuring a qubit of the output plurality of qubits comprises measuring a last qubit of the output plurality of qubits to obtain duplicated qubits |ψ² [symbol] .

5. The method of claim 1, wherein applying sequentially a plurality of CNOT operators comprises:
applying a first CNOT operator (gate X) with a control qubit |ψ [symbol] and controlling (target) state |0 [symbol] to form a result comprising a 2-qubit state |φ [symbol] =a|00 [symbol] +b|11 [symbol] ;
applying a second CNOT operator with the control qubit |ψ [symbol] and a second input being |φ [symbol] ); wherein the target is a first qubit of |ψ [symbol] , to form a result comprising a 4-qubit output state having duplicated qubits in the 2^{nd} and 4^{th} qubits of the output state.

6. The method of claim 4, further comprising:
applying a permutation of a 3-qubit state, to swap a first qubit and a second qubit of the second CNOT operator.

7. The method of claim 6, wherein applying a 2-Controlled-NOT operator comprises:
applying a 2-Controlled-NOT operator with a target qubit number of 3 to the output of the second CNOT operator to output a plurality of qubits

8. The method of claim 7, wherein measuring a qubit of the output plurality of qubits comprises measuring a last qubit of the output plurality of qubits to obtain duplicated qubits |ψ² [symbol] .

9. A system for copying a qubit comprising:
a plurality of CNOT operator circuits sequentially connected and configured to receive a qubit in a genetic state of linear superposition |ψ [symbol] =a|0 [symbol] +b|1 [symbol] and to form therefrom a result comprising a 4-qubit output state having duplicated qubits in a plurality of qubits of the output state;
circuitry configured to measure the 4-qubit output state;
a 2-Controlled-NOT operator circuit configured with a target qubit input connected to the output of the second CNOT operator to output a plurality of qubits; and
circuitry configured to measure a qubit of the output plurality of qubits to obtain duplicated qubits |ψ² [symbol] .

10. The system of claim 9, wherein the plurality of CNOT operator circuits comprise:
a first CNOT operator circuit (gate X) comprising a control qubit |ψ [symbol] input and a controlling (target) state |0 [symbol] input, and an output outputting a result comprising a 2-qubit state |φ [symbol] =a|00 [symbol] +b|11 [symbol] ;
a second CNOT operator circuit comprising a control qubit |ψ [symbol] , a second input of |φ [symbol] , and a target input of a second qubit of |φ [symbol] , and an output outputting a result comprising a 4-qubit output state having duplicated qubits in the 2^{nd} and 3^{rd} qubits of the output state.

11. The system of claim 9, wherein the 2-Controlled-NOT operator circuit is configured to apply a 2-Controlled-NOT operator with a target qubit number of 3 to the output of the second CNOT operator to output a plurality of qubits.

12. The system of claim 11, wherein the circuitry configured to measure a qubit of the output plurality of qubits is further configured to measure a last qubit of the output plurality of qubits to obtain duplicated qubits |ψ² [symbol] .

13. The system of claim 9, wherein the plurality of CNOT operator circuits comprise:
a first CNOT operator circuit (gate X) comprising a control qubit |ψ [symbol] input and a controlling (target) state |0 [symbol] input, and an output outputting a result comprising a 2-qubit state |φ [symbol] =a|00 [symbol] +b|11 [symbol] ;
a second CNOT operator circuit comprising a control qubit |ψ [symbol] , a second input of |φ [symbol] , and a target input of a first qubit of |φ [symbol] , and an output outputting a result comprising a 4-qubit output state having duplicated qubits in the 2^{nd} and 4^{th} qubits of the output state.

14. The system of claim 12, further comprising:
permutation circuitry configured to apply a permutation of a 3-qubit state, to swap a first qubit and a second qubit of the second CNOT operator.

15. The system of claim 14, wherein the 2-Controlled-NOT operator circuit is configured to apply a 2-Controlled-NOT operator with a target qubit number of 3 to the output of the second CNOT operator to output a plurality of qubits.

16. The system of claim 15, wherein the circuitry configured to measure a qubit of the output plurality of qubits is further configured to measure a last qubit of the output plurality of qubits to obtain duplicated qubits |ψ² [symbol] .
